(19) United States
(12) Patent Application Publication
(10) Pub. No.: US 2025/0372513 A1
(43) Pub. Date: Dec. 4, 2025

(54) SEMICONDUCTOR STRUCTURES AND FABRICATION METHODS THEREOF, SEMICONDUCTOR DEVICES AND FABRICATION METHODS THEREOF

(71) Applicant: Yangtze Memory Technologies Co., Ltd., Wuhan (CN)

(72) Inventors: Wenjing Xiao, Wuhan (CN); Libo Mei, Wuhan (CN); Huan Wang, Wuhan (CN); Liang Xiao, Wuhan (CN); Zhen Pan, Wuhan (CN); Yaqin Liu, Wuhan (CN)

(21) Appl. No.: 18/805,210

(22) Filed: Aug. 14, 2024

(30) Foreign Application Priority Data
May 28, 2024 (CN) 202410683175.0

(51) Int. Cl. H01L 23/528; G11C 16/04; H10B 41/10; H10B 41/35; H10B 41/41; H10B 43/10; H10B 43/35; H10B 43/40

(52) U.S. Cl. CPC H01L 23/5283; G11C 16/0483; H10B 41/10; H10B 41/35; H10B 41/41; H10B 43/10; H10B 43/35; H10B 43/40

(57) ABSTRACT

The present disclosure provides a semiconductor structure and a fabrication method thereof, a semiconductor device and a fabrication method thereof, and relate to the technical field of semiconductors. The semiconductor structure includes an interconnection layer and a bonding layer. The interconnection layer includes a first interconnection portion and a second interconnection portion. The bonding layer includes a bonding portion and a third interconnection portion. The first interconnection portion is connected with the second interconnection portion through the third interconnection portion. In the semiconductor structure provided by an example of the present disclosure, interconnection portions in the interconnection layer can be reduced by disposing the third interconnection portion in the bonding layer, thereby reducing the cost.

### CROSS-REFERENCE TO RELATED APPLICATION

The present disclosure claims the benefit of priority to China Application No. 202410683175.0, filed on May 28, 2024, the content of which is incorporated herein by reference in its entirety.

### TECHNICAL FIELD

The present disclosure relates to the technical field of semiconductors, and particularly to semiconductor structures, semiconductor devices, fabrication methods of semiconductor structures, and fabrication methods of semiconductor devices.

### BACKGROUND

As the critical dimension of the semiconductor manufacturing process becomes increasingly small, the storage density of a memory device becomes increasingly high. In order to further increase the storage density, a memory device with a three-dimensional structure (referred to as 3D memory device) has been developed. The 3D memory device comprises a plurality of memory cells stacked along a vertical direction, allowing for an exponential increase in the level of integration per unit area of a die and a reduction in costs.

The 3D memory device is mainly used as a non-volatile flash memory. Two primary non-volatile flash memory technologies adopt NAND and NOR structures respectively. In the 3D memory device with the NAND structure, the number of stacking layers of a stack structure is a key technical index, and increasing the number of stacking layers is the most effective way to improve the storage density.

### BRIEF DESCRIPTION OF THE DRAWINGS

FIG. 1 illustrates a top view of a semiconductor structure in an example of the present disclosure.

FIG. 2 illustrates a cross-sectional view of the semiconductor structure shown in FIG. 1.

FIG. 3 illustrates a cross-sectional view of another semiconductor structure in an example of the present disclosure.

FIG. 4 illustrates a cross-sectional view of still another semiconductor structure in an example of the present disclosure.

FIG. 5 illustrates a cross-sectional view of yet another semiconductor structure in an example of the present disclosure.

FIG. 6 illustrates a cross-sectional view of yet another semiconductor structure in an example of the present disclosure.

FIG. 7 illustrates a cross-sectional view of yet another semiconductor structure in an example of the present disclosure.

FIG. 8 illustrates a cross-sectional view of yet another semiconductor structure in an example of the present disclosure.

FIG. 9 illustrates a cross-sectional view of yet another semiconductor structure in an example of the present disclosure.

FIG. 10 illustrates a cross-sectional view of yet another semiconductor structure in an example of the present disclosure.

FIG. 11 illustrates a cross-sectional view of yet another semiconductor structure in an example of the present disclosure.

FIG. 12 illustrates a cross-sectional view of yet another semiconductor structure in an example of the present disclosure.

FIG. 13 illustrates a cross-sectional view of yet another semiconductor structure in an example of the present disclosure.

FIG. 14 illustrates a cross-sectional view of yet another semiconductor structure in an example of the present disclosure.

FIG. 15 illustrates a cross-sectional view of a semiconductor device in an example of the present disclosure.

FIG. 16 illustrates a cross-sectional view of another semiconductor device in an example of the present disclosure.

FIG. 17 illustrates a cross-sectional view of still another semiconductor device in an example of the present disclosure.

FIG. 18 illustrates a cross-sectional view of yet another semiconductor device in an example of the present disclosure.

FIG. 19 illustrates a cross-sectional view of yet another semiconductor device in an example of the present disclosure.

FIG. 20 illustrates a cross-sectional view of yet another semiconductor device in an example of the present disclosure.

FIG. 21 illustrates a cross-sectional view of yet another semiconductor device in an example of the present disclosure.

FIG. 22 illustrates a cross-sectional view of yet another semiconductor device in an example of the present disclosure.

FIG. 23 illustrates a cross-sectional view of yet another semiconductor device in an example of the present disclosure.

FIG. 24 illustrates a cross-sectional view of yet another semiconductor device in an example of the present disclosure.

FIG. 25 illustrates a cross-sectional view of yet another semiconductor device in an example of the present disclosure.

FIG. 26 illustrates a cross-sectional view of yet another semiconductor device in an example of the present disclosure.

FIG. 27 illustrates a cross-sectional view of yet another semiconductor device in an example of the present disclosure.

FIG. 28 illustrates a cross-sectional view of yet another semiconductor device in v of the present disclosure.

FIG. 29 illustrates a cross-sectional view of yet another semiconductor device in an example of the present disclosure.

FIG. 30 illustrates a cross-sectional view of yet another semiconductor device in v of the present disclosure.

FIG. 31 illustrates a cross-sectional view of yet another semiconductor device in an example of the present disclosure.

FIG. 32 illustrates a flow chart of a fabrication method of a semiconductor structure in an example of the present disclosure.

FIG. 33 illustrates a flow chart of a fabrication method of a semiconductor device in an example of the present disclosure.

FIG. 34 illustrates a block diagram of an example system having a memory in an example of the present disclosure.

FIG. 35 exemplarily illustrates a block diagram of a memory system.

FIG. 36 exemplarily illustrates a block diagram of another memory system.

FIG. 37 is a schematic circuit diagram of a memory comprising a peripheral circuit provided by an example of the present disclosure.

FIG. 38 is a schematic diagram of a peripheral circuit provided by an example of the present disclosure.

### DETAILED DESCRIPTION

Examples are described more comprehensively with reference to the drawings. However, examples may be implemented in various forms and should not be construed as being limited to the examples set forth herein. In contrast, these examples are provided for a more thorough and complete understanding of the present disclosure, and to fully convey the concept of the examples to those skilled in the art. The drawings are merely schematic illustrations of the present disclosure and are not necessarily drawn to scale. The same reference signs in the drawings denote same or similar portions, and thus the repetitive descriptions thereof will be omitted.

Furthermore, the described features, structures or characteristics may be combined in one or more examples in any proper manner. In the following descriptions, many specific details are provided thereby giving a full understanding of the examples of the present disclosure. However, those skilled in the art will realize that the technical solutions of the present disclosure may be practiced with one or more of the particular details being omitted, or other methods, devices, operations, etc., may be employed. In other cases, well-known structures, methods, devices, implementations, or operations are not shown or described in detail to avoid overshadowing and obscuring aspects of the present disclosure.

Furthermore, the terms “first”, “second” and the like are used for descriptive purposes only and are not to be construed as indicating or implying relative importance or implicitly specifying the number of technical features indicated. Thus, features defined by “first” and “second” may explicitly or implicitly include one or more of such features. In the description of the present disclosure, “a plurality of” means at least two, for example, two, three, or the like, unless otherwise explicitly specified. The symbol “/” generally indicates that the objects related to each other by it are in an “or” relationship.

In the present disclosure, unless otherwise explicitly specified and defined, the terms “connect”, “couple” and the like should be interpreted broadly. For example, the terms may be interpreted as electrical connection or mutual communication, and may be interpreted as direct connection or indirect connection realized by a medium. For those of ordinary skills in the art, particular meanings of the above terms in the present disclosure may be understood based on particular situations.

It is to be understood readily that, for ease of description, spatially relative terms, such as “under”, “underneath”, “below”, “over”, “on” and the like, may be used herein to describe the relationship of one element or feature with respect to another (other) element(s) or feature(s) as illustrated in the drawings. The terms in the present disclosure should be construed in the broadest manner, for example, the meaning of “on” is not only “directly on something”, but also includes the meaning of “above something” with the presence of an intermediate feature or layer therebetween. In addition, “above” or “over” implies not only the meaning of “over something” or “above something”, but also may include the meaning of “over something” or “above something” with the absence of an intermediate feature or layer therebetween (i.e., directly on something).

The spatially relative terms are intended to encompass different orientations of a device in use or operation in addition to the orientations as illustrated in the drawings. The device may be otherwise oriented (rotated 90 degrees or in other orientations) and the spatially related descriptors used herein may likewise be interpreted accordingly. Moreover, if the device is turned over, then the one layer or region will be “under” or “below” another layer or region.

As used herein, the term “substrate” refers to a material onto which subsequent material layers are added. The substrate itself can be patterned. Materials added on top of the substrate can be patterned or can remain non-patterned. Furthermore, the substrate may include a variety of semiconductor materials, such as silicon, germanium, gallium arsenide, indium phosphide and the like. Alternatively, the substrate may be made from a non-conductive material, such as a glass, a plastic, or a sapphire wafer.

As used herein, the term “layer” refers to a material portion comprising a region with a thickness. A layer may extend over the entire underlying or overlying structure or may have an extent less than the extent of the underlying or overlying structure. Furthermore, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may comprise one or more layers therein, and/or may have one or more layer thereon, thereabove, and/or therebelow. A layer may comprise a plurality of layers. For example, an interconnection layer may comprise one or more conductor and contact layers (in which at least one of an interconnection wire or a via contact is formed) and one or more dielectric layers.

In the present disclosure, the term “semiconductor structure” refers to a general term of the entire semiconductor structure formed in operations of manufacturing a memory device, comprising all layers or regions that have been formed. In the following, unless otherwise indicated, the “semiconductor structure” refers to an intermediate structure comprising a die/wafer and a gate stack structure formed therein.

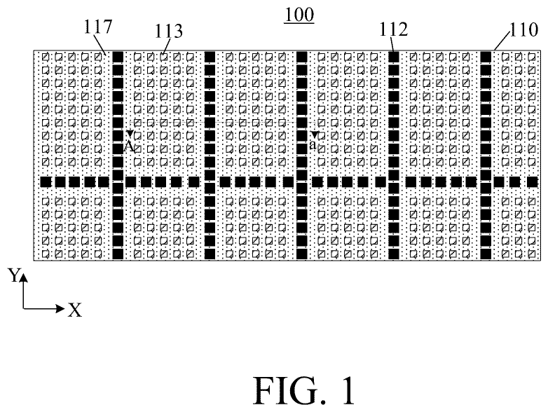

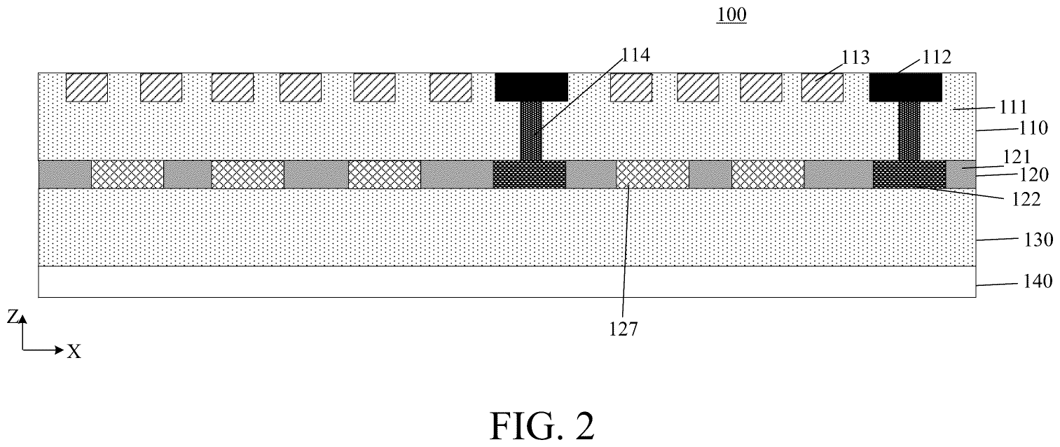

As used herein, the term “three-dimensional (3D) memory device” refers to a semiconductor device having a vertically oriented (e.g., the Z axis shown in FIG. 2) memory cell transistor string (referred to as “memory string” herein, such as NAND string) on a laterally oriented (e.g., the X axis shown in FIG. 1) substrate so that the memory string extends in the vertical direction with respect to the substrate. As used herein, the term “vertical/vertically” refers to being nominally perpendicular to a lateral surface of the substrate.

An X-tacking architecture enables the processing of peripheral circuits and memory cells on two individual wafers, for example, a wafer for processing the peripheral circuits is referred to as a peripheral wafer or CMOS wafer, and a wafer for processing the memory is referred to as an array wafer. This facilitates the selection of a more advanced logic process, thus allowing the NAND to acquire a higher I/O interface speed and more operational functions. Once the two wafers are finished respectively, the Xtacking technology may bond the two wafers together in just one processing operation through billions of vertical interconnection channels (vias). As such, a higher storage density is realized, and a chip area is reduced. Meanwhile, by taking full advantage of the independent processing of the memory cells and the peripheral circuits, parallel and modular product design and manufacturing can be realized, thereby shortening a production cycle.

Under the X-tacking architecture, with the development of technical generations, back-end-of-line metal layers of the array wafer gradually develop from 2 layers to 3 layers, and back-end-of-line metal layers of the CMOS wafer develop from the previous 3 layers to 5 layers, 6 layers, and 7 layers. If the thickness of a metal trace is decreased constantly, the resistance of the metal trace may be increased due to a reduction in the cross-sectional area of a metal wire, affecting conductivity of the metal trace. If a design demand for routing is met by increasing the number of metal layers, the process complexity is increased and the manufacturing cost is increased.

However, with the increase of the number of stacking layers, the demand for a back-end-of-line metal routing becomes increasingly high, the number of back-end-of-line metal layers of an array wafer/peripheral wafer (for example, which may adopt a CMOS process and be referred to as a CMOS wafer) becomes increasingly large, and accordingly, the manufacturing cost becomes increasingly high.

As shown in FIG. 1, a semiconductor structure 100 provided by an example of the present disclosure comprises a bonding layer 110, the bonding layer 110 comprising a bonding portion that comprises a first bonding contact 112 and a second bonding contact 113. A region in the bonding layer 110 that is provided with no bonding portion is a blank region 117 (i.e., a region having no via hole or contact) thereof. The Y axis in FIG. 1 represents a longitudinal direction intersecting (e.g., perpendicular to) the X axis.

FIG. 2 is a cross-sectional view of the semiconductor structure 100 shown in FIG. 1 along a line Aa. As shown in FIG. 2, the semiconductor structure 100 comprises a substrate 140, and a device layer 130, an interconnection layer 120, and the bonding layer 110 stacked sequentially on the substrate 140. For the sake of simplicity, a functional layer located in the device layer 130 between the substrate 140 and the interconnection layer 120 is not shown in FIG. 2. An internal structure of the functional layer in the device layer 130 is related to a chip type. The functional layer provides at least a portion of a structure of a transistor. For example, source and drain regions of the transistor are formed in the substrate 140, and a gate stack structure of the transistor is formed in the functional layer. When the semiconductor structure 100 is a 3D memory device chip (e.g., an array wafer), the gate stack structure in the functional layer comprises a plurality of gate conductor layers, a plurality of interlayer insulation layers for separating adjacent gate conductor layers, and a channel pillar extending through the gate stack structure. When the semiconductor structure 100 is a drive circuit chip (e.g., a peripheral wafer), the gate stack structure in the functional layer comprises, for example, a single gate conductor layer.

The semiconductor structure 100 shown in FIG. 1 and FIG. 2 is not limited to the CMOS and array wafers, and may be any single wafer.

The bonding layer 110 may comprise a dielectric layer 111, e.g., including silicon dioxide. A first bonding contact 112 and a second bonding contact 113 are formed in the dielectric layer 111. The interconnection layer 120 may comprise an electrical insulation layer 121, e.g., including silicon dioxide. A seventh interconnection portion 122 and an eighth interconnection portion 127 are disposed in the electrical insulation layer 121. In the dielectric layer 111, the first bonding contact 112 and a first conductive channel 114 constitute a dual damascene structure. The first bonding contact 112 is connected with the seventh interconnection portion 122 in the interconnection layer 120 through the first conductive channel 114, so as to achieve coupling with a device in the device layer 130, e.g., contact with an active region in at least one of the substrate 140 or the device layer 130. That is, the seventh interconnection portion refers to an interconnection portion that is located in the interconnection layer and coupled/connected with the first bonding contact and the device in the device layer, respectively. There is no conductive channel in the dielectric layer 111 that is connected with the second bonding contact 113, which is therefore not connected with the eighth interconnection portion 127 in the interconnection layer 120 and thus not coupled with the device in the device layer 130. That is, the eighth interconnection portion refers to an interconnection portion that is located in the interconnection layer and not coupled/connected with at least one of the second bonding contact or the device in the device layer.

The first bonding contact 112 refers to a via hole or contact, also denoted as active hole(s) or functional bonding contact, that is actually involved in an electrical connection or a functional implementation on a bonding interface when the semiconductor structure 100 is bonded with other semiconductor structures to form the bonding interface. These via holes may be metallized via holes (e.g., copper pillar bumps) used to realize an inter-wafer or inter-chip electrical connection.

The second bonding contact 113 refers to a non-functional via hole or contact, also denoted as dummy hole(s) or dummy bonding contact, that is disposed on a bonding interface when the semiconductor structure 100 is bonded with other semiconductor structures to form the bonding interface. The dummy hole(s) may be used to maintain process consistency, e.g., distribute via holes on a wafer uniformly to control a thermal or mechanical stress. The dummy hole(s) may also be used as alignment mark(s) to help precisely align different wafers or chips during a bonding process. In some cases, the dummy hole(s) may be filled with a conductive or non-conductive material to provide extra mechanical support or electrical insulation. The second bonding contact is not used to realize an inter-wafer or inter-chip electrical connection.

The seventh interconnection portion 122 and the eighth interconnection portion 128 in the interconnection layer 120 may be metal traces inside the semiconductor structure 100 that may form a metal layer and implement an electrical connection between different layers at a position requiring a connection, through metallized via holes (e.g., copper pillar bumps, metallized via holes, etc.) which are designed to be conductive.

During the bonding process, precise control on positions, dimensions and distributions of the active hole(s) and dummy hole(s) is critical to ensure package quality and performance. These parameters are usually required to be set according to a particular wafer dimension, a package type, a circuit design, and a process requirement. By optimizing configurations of the active hole(s) and dummy hole(s), the package reliability may be increased, the cost may be reduced, and the overall performance may be improved. It may be understood that the above numbers and distributions of the active hole(s) and the dummy hole(s) in FIG. 1 and FIG. 2 are only examples, and the present disclosure is not limited thereto.

As can be seen from FIG. 1 and FIG. 2, the dummy hole(s) 113 and the blank region 117 have a large area in the bonding layer 110. Accordingly, at least a portion of at least one of the dummy hole(s) 113 or blank region 117 having a large area in the bonding layer 110 (i.e., a region in the bonding layer without a trace) may be further utilized to arrange at least a part of routings of the interconnection portions of the interconnection layer 120, thus metal routing in the interconnection layer 120 may be reduced, for example, one layer of the metal routing is reduced so that the cost is reduced and the process operations are reduced.

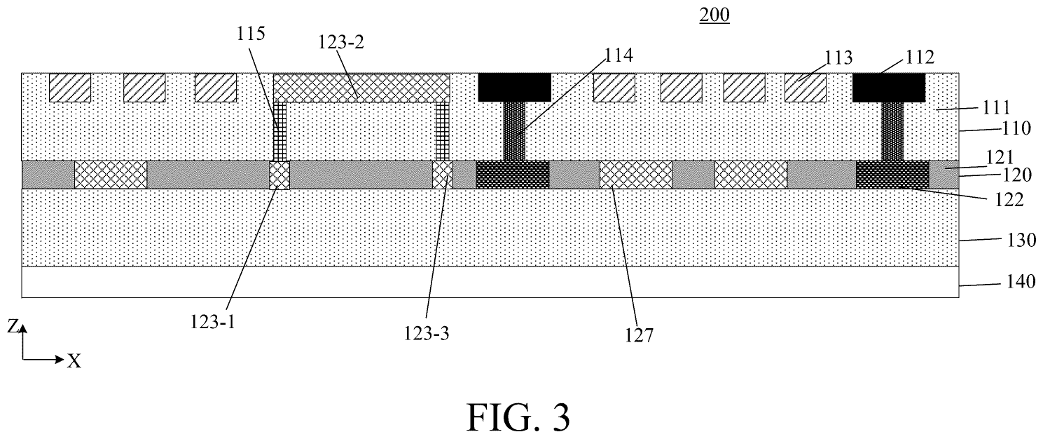

An examples of the present disclosure provide a semiconductor structure comprising an interconnection layer and a bonding layer. The interconnection layer comprises a first interconnection portion and a second interconnection portion. The bonding layer comprises a bonding portion and a third interconnection portion. The first interconnection portion in the interconnection layer is connected with the second interconnection portion in the interconnection layer through the third interconnection portion in the bonding layer. That is, by disposing a part of routings of at least parts of the interconnection portions of the interconnection layer into the bonding layer, the routings of the interconnection portions in the interconnection layer may be reduced, thereby simplifying the process operations of the interconnection layer and reducing the cost. Meanwhile, the trace width of the interconnection portions in the interconnection layer may be maintained, avoiding an increase in the resistance of the interconnection portions due to a reduction in the cross-sectional area of the interconnection portions. The semiconductor structures provided by the examples of the present disclosure are illustrated below with examples in conjunction with FIG. 3 to FIG. 14, but the present disclosure is not limited thereto.

As shown in FIG. 3, a semiconductor structure 200 provided by an example of the present disclosure comprises the substrate 140, and the device layer 130, the interconnection layer 120, and the bonding layer 110 stacked sequentially on the substrate 140. The interconnection layer 120 may comprise the electrical insulation layer 121, and the seventh interconnection portion 122 and the eighth interconnection portion 127 are disposed in the electrical insulation layer 121. The bonding layer 110 may comprise the dielectric layer 111, and the first bonding contact 112 and the second bonding contact 113 are disposed in the dielectric layer 111. The first bonding contact 112 is connected with the seventh interconnection portion 122 in the interconnection layer 120 through the first conductive channel 114, so as to realize coupling with the device in the device layer 130. There is no conductive channel that connects the second bonding contact 113 with the eighth interconnection portion 127, and thus the second bonding contact 113 is not coupled with the device in the device layer 130.

In the example of FIG. 3, the interconnection layer 120 further comprises a first interconnection portion 123-1 and a second interconnection portion 123-3, and the bonding layer 110 further comprises a third interconnection portion 123-2. The first interconnection portion 123-1 in the interconnection layer 120 is connected/coupled with the second interconnection portion 123-3 in the interconnection layer 120 through the third interconnection portion 123-2 in the bonding layer 110. In the examples of the present disclosure, the first interconnection portion and the second interconnection portion refer to two interconnection portions that are located in the interconnection layer, coupled with a device in the device layer, and coupled with each other through the third interconnection portion in the bonding layer. The first interconnection portion and the second interconnection portion are not coupled with the first bonding contact in the bonding layer, that is, the first interconnection portion and the second interconnection portion are not used to realize an inter-wafer or inter-chip electrical connection, but are used to realize an electrical connection between the devices within a current wafer or chip. The third interconnection portion refers to an interconnection portion that is located in the bonding layer and connected with the first interconnection portion and the second interconnection portion in the interconnection layer respectively to realize coupling with the device in the device layer. It may be also understood that at least one interconnection portion in the semiconductor structure comprises two parts, with one of the two parts included in the interconnection portion that is disposed in the interconnection layer 120 being referred to as a first part (e.g., the first interconnection portion 123-1 and the second interconnection portion 123-3) of the interconnection portion, and the other one of the two parts that is disposed in the bonding layer 110 being referred to as a second part (e.g., the third interconnection portion 123-2) of the interconnection portion.

In the examples of the present disclosure, a region in the bonding layer 110 that is used to dispose the first bonding contact 112 of the bonding portion is referred to as a first region, a region in the bonding layer 110 other than the first bonding contact 112 is referred to as a second region, and the third interconnection portion 123-2 is distributed in the second region of the bonding layer 110. The second region may be at least a part of regions of at least one of the above blank region 117 or second bonding contact 113 in FIG. 1 and FIG. 2. That is, in the examples of the present disclosure, the second part (e.g., the third interconnection portion 123-2) of the interconnection portion is disposed in a region in the bonding layer that is not used to arrange the first bonding contact having an electrical connection function, so as to reduce the number of routing layers of the interconnection portions in the interconnection layer, without affecting the distribution of first bonding contacts in the bonding layer, that is, the distribution of the original active hole(s) may remain unchanged.

In an example, the interconnection portion is a metal trace. Since a metal seal ring is fabricated around the semiconductor structure 200, which is a metal trace per se, i.e., a fabrication process of the bonding layer of the semiconductor structure 200 comprises the fabrication of both the metal trace and metal hole, just some metal traces are added in the bonding layer in the example of the present disclosure, that is, at least a part of internal metal traces in the CMOS or array interconnection layer are added in at least one of the original blank region or the position of the dummy hole(s) in the bonding layer, imposing a very small impact on the original process.

With continued reference to FIG. 3, a part of the routings (jumping wires) that cannot be completely laid out in a topmost metal layer in the interconnection layer inside the semiconductor structure 200 (e.g., CMOS or array wafer) may be routed to the bonding layer 110 through a second conductive channel 115 to form the third interconnection portion 123-2, and then goes downward after reaching a destination electrical connection point, so as to be connected with the second interconnection portion 123-3 through the second conductive channel 115. As such, an actual metal connection relationship within the semiconductor structure 200 may be unaffected, and just a part of the metal routings are routed into the bonding layer 110, so as avoid providing an additional metal layer in the interconnection layer 120. In some other examples, there may be no second conductive channel 115, as long as the coupling between the first interconnection portion 123-1 and the second interconnection portion 123-3 can be achieved through the third interconnection portion 123-2.

In the example of FIG. 3, in addition to the first interconnection portion and the second interconnection portion described above, interconnection portions in the interconnection layer 120 that are coupled with the first bonding contact 112 is denoted as the seventh interconnection portions 122, and interconnection portions in the interconnection layer 120 that are not coupled with the first bonding contact 112 or the second bonding contact 113 are denoted as the eighth interconnection portions 127. The interconnection portion for arranging a part of the routings into the bonding portion may be at least one of the eighth interconnection portions 127. In the examples of the present disclosure, a part of the routings of the interconnection portion that is not required to be electrically connected with the bonding portion are disposed into the bonding layer, so that the process operations may be simplified without affecting the electrical connection between the seventh interconnection portions 122 and the bonding portion.

In some examples, the seventh interconnection portions 122 are functional MEOL or BEOL interconnections (e.g., interconnection wires or via hole contacts) that are electrically connected to the device layer 130. The eighth interconnection portions 127 may be functional MEOL or BEOL interconnections (e.g., interconnection wires or via hole contacts) that may be electrically connected to the device layer 130 or may be not electrically connected to the device layer 130. In some examples, the eighth interconnection portions 127 are dummy interconnections that are not electrically connected to the device layer 130.

In the examples of the present disclosure, the interconnection portions may include conductive material, including, but not limited to, W, Co, Cu, Al, silicide, or any combination thereof. The electrical insulation layer 121 in the interconnection layer 120 may include a dielectric material, including, but not limited to, silicon oxide, silicon nitride, silicon oxynitride, a low-k dielectric, or any combination thereof.

In the example of FIG. 3, when the second part of at least parts of the interconnection portions is added in the bonding layer 110, the second bonding contact 113 included in the bonding layer 110 may still remain in the form of a contact or a hole, thereby allowing compatibility with the original fabrication process and reducing the complexity of the fabrication process.

It is to be noted that the present disclosure does not limit a trace spacing between the second part of the interconnection portions and the first bonding contact 112 and the second bonding contact 113 in the bonding layer, as long as it meets a respective design rule.

The semiconductor structure 200 shown in FIG. 3 is not limited to the CMOS or array wafer, but may be fabricated into any wafer, as long as it utilizes at least one of the blank region or the position(s) of the original dummy hole(s) in the bonding layer to lay out the metal traces inside the wafer.

In the example of FIG. 3, the first bonding contact 112 and the first conductive channel 114 employ a dual damascene process, i.e., involve two patterning processes (e.g., two lithography and development processes), so as to increase a bonding yield. Meanwhile, by implementing a reasonable distribution of the first bonding contact 112, the second bonding contact 113, and the third interconnection portion 123-2 in the bonding layer, the required uniformity of metal and dielectric distribution may be achieved, so that non-uniformity of corrosion control and recess control of the device during a subsequent chemical mechanical polishing (CMP) process can be avoided. That is, the third interconnection portion may be used to implement the connection between the first interconnection portion and the second interconnection portion and may also function as a dummy bonding contact.

In an example, the device included in the device layer 130 is a memory device or a peripheral device.

In some examples, the semiconductor structure 200 is a peripheral device chip or a memory array device chip, and the device layer 130 comprises a peripheral device or a NAND memory string.

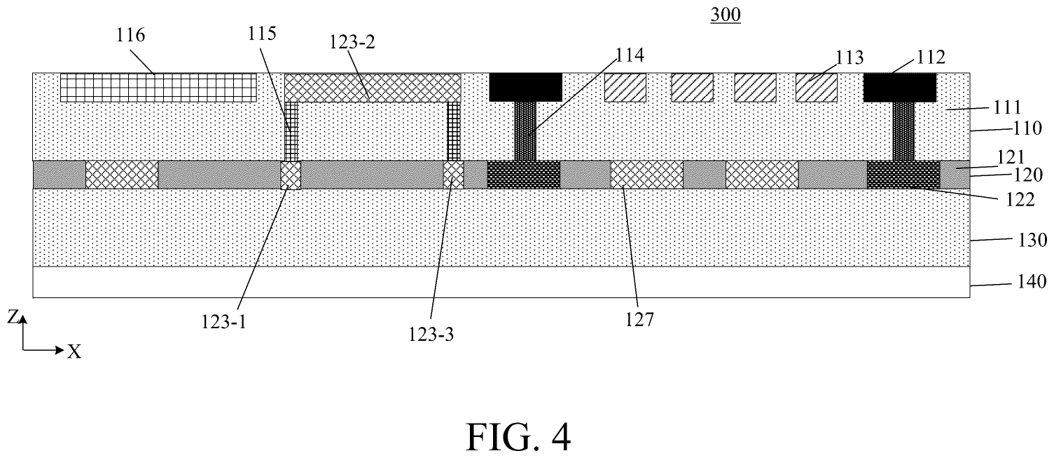

A semiconductor structure 300 shown in the example of FIG. 4 differs from the semiconductor structure 200 shown in the example of FIG. 3 in that, when the second part of at least parts of the interconnection portions is added in the bonding layer 110, at least parts of second bonding contacts 113 included in the bonding layer 110 may be formed integrally using a conductive material, such as metal, here referred to as a first bonding wire 116, so as to be distinguished from the second bonding contact 113 formed in the form of a contact or hole. The first bonding wire 116 is not connected with the seventh interconnection portion 122, the eighth interconnection portion 127, the first interconnection portion 123-1 or the second interconnection portion 123-3 in the interconnection layer 120, i.e., not coupled with the device in the device layer 130. Since a dimension of a single first bonding wire 116 is greater than a dimension of a single second bonding contact 113, the resistance of the metal may be reduced by increasing a trace width of the first bonding wire.

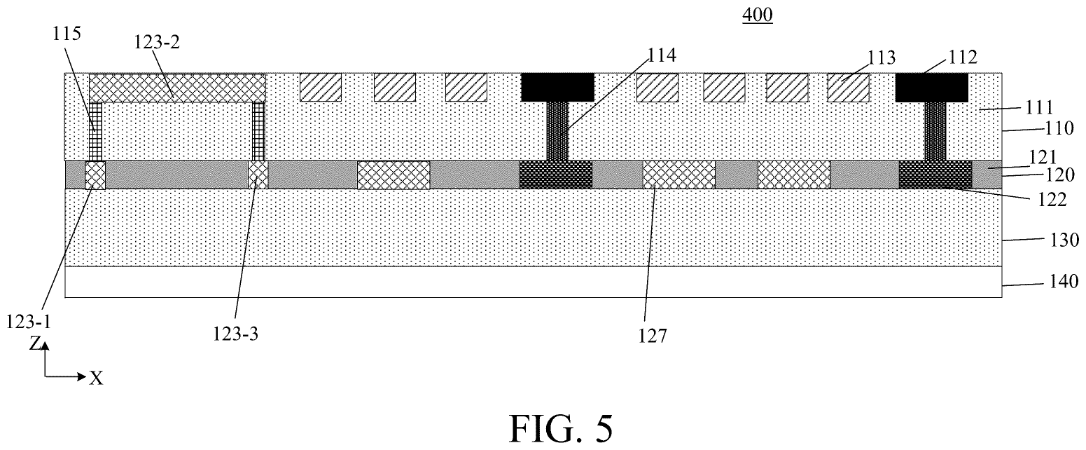

A semiconductor structure 400 shown in the example of FIG. 5 differs from the semiconductor structure 200 shown in the example of FIG. 3 in that, the third interconnection portion 123-2 in the bonding layer 110 may be spaced apart from the first bonding contact 112 by at least one second bonding contact 113. The third interconnection portion 123-2 is spaced apart from the first bonding contact 112 by the second bonding contact that is not required to realize an electrical connection function, so that interference between the third interconnection portion and the first bonding contact may be avoided.

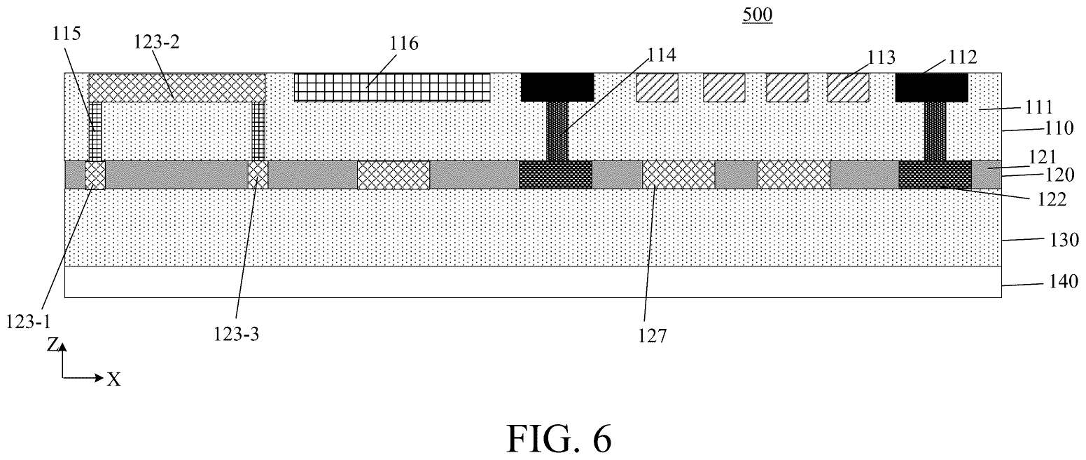

A semiconductor structure 500 shown in the example of FIG. 6 differs from the semiconductor structure 300 shown in the example of FIG. 4 in that, the third interconnection portion 123-2 in the bonding layer 110 may be spaced apart from the first bonding contact 112 by at least one first bonding wire 116. The third interconnection portion 123-2 is spaced apart from the first bonding contact 112 by the first bonding wire that is not required to realize an electrical connection function, so that interference between the third interconnection portion and the first bonding contact may be avoided.

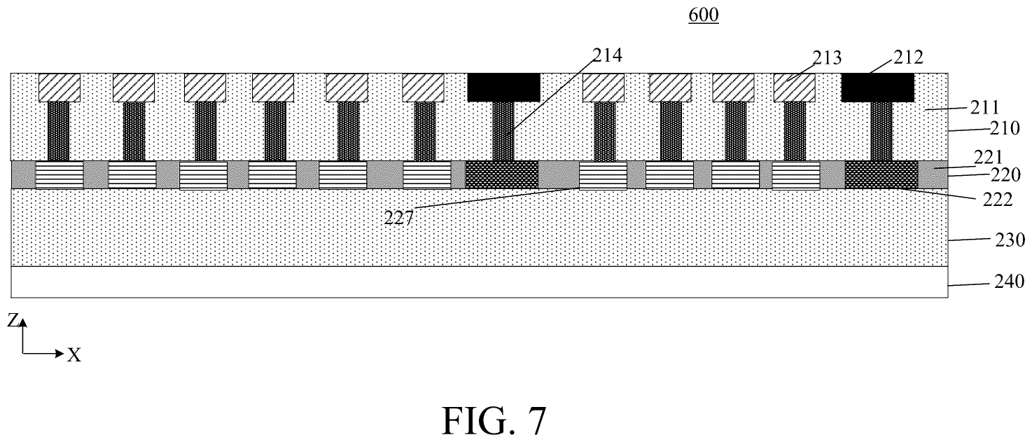

A semiconductor structure 600 shown in the example of FIG. 7 comprises a substrate 240, and a device layer 230, an interconnection layer 220, and a bonding layer 210 stacked sequentially on the substrate 240. The interconnection layer 220 comprises an electrical insulation layer 221 in which seventh interconnection portions 222 and eighth interconnection portions 227 may be arranged at intervals. The bonding layer 210 comprises a dielectric layer 211 in which first bonding contacts 212 and second bonding contacts 213 may be arranged at intervals. The example of FIG. 7 differs from the example of FIG. 2 in that, the first bonding contact 212 and the second bonding contact 213 both may be electrically connected with the seventh interconnection portion 222 and the eighth interconnection portion 227 in the interconnection layer 220 respectively through a first conductive channel 214. The seventh interconnection portion 222 is electrically connected with a device in the device layer 230, and the seventh interconnection portion 222 therefore may be referred to as a functional interconnection portion. The eighth interconnection portion 227 is not electrically connected with a device in the device layer 230, and therefore may be referred to as a dummy interconnection portion. Forming the first bonding contact and the second bonding contact through the same process can simplify a fabrication process of the bonding portion. Meanwhile, an electrical connection between the first bonding contact and the device in the device layer can be implemented, whereas the second bonding contact is not electrically connected with the device in the device layer.

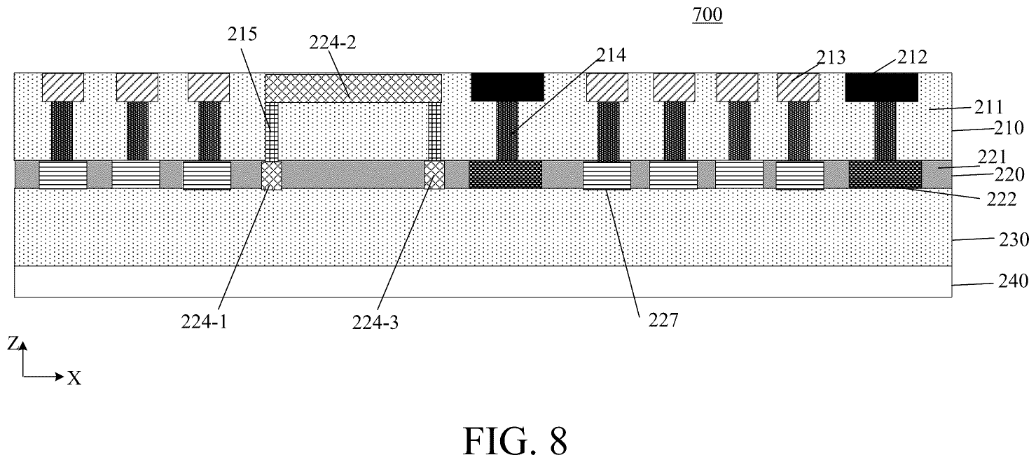

A semiconductor structure 700 illustrated in the example of FIG. 8 differs from the example of FIG. 7 in that, the interconnection layer 220 further comprises a first interconnection portion 224-1 and a second interconnection portion 224-3. The bonding layer 210 further comprises a third interconnection portion 224-2. The third interconnection portion 224-2 is connected with the first interconnection portion 224-1 and the second interconnection portion 224-3 respectively through a second conductive channel 215. On the one hand, disposing the second part of at least parts of the interconnection portions in the bonding layer can reduce the cost. On the other hand, forming the first bonding contact and the second bonding contact through the same process can simplify a fabrication process of the bonding portion. Meanwhile an electrical connection between the first bonding contact and the device in the device layer can be implemented, whereas the second bonding contact is not electrically connected with the device in the device layer.

In the example of FIG. 8, when the second part of at least parts of the interconnection portions is added in the bonding layer 210, the second bonding contact 213 included in the bonding layer 210 may still remain in the form of a contact or a hole, thereby allowing compatibility with the original fabrication process and reducing the complexity of the fabrication process.

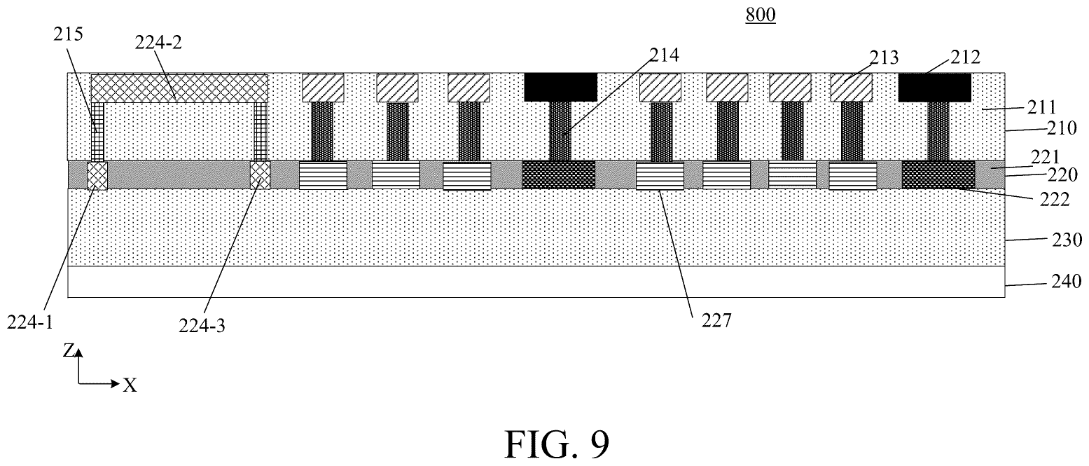

A semiconductor structure 800 illustrated in the example of FIG. 9 differs from the example of FIG. 8 in that, the third interconnection portion 224-2 in the bonding layer 210 may be spaced apart from the first bonding contact 212 by at least one second bonding contact 213. The third interconnection portion 224-2 is spaced apart from the first bonding contact 212 by the second bonding contact that is not required to realize an electrical connection function, so that interference between the third interconnection portion and the first bonding contact may be avoided.

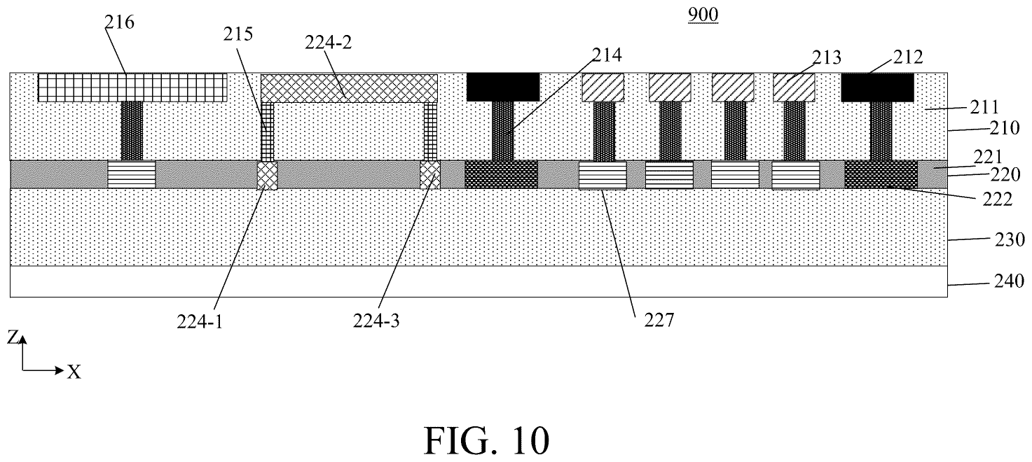

A semiconductor structure 900 illustrated in the example of FIG. 10 differs from the example of FIG. 8 in that, when the third interconnection portion 224-2 is added in the bonding layer 210, at least parts of second bonding contacts 213 included in the bonding layer 210 may be formed integrally using a conductive material, such as metal, here referred to as a first bonding wire 216, so as to be distinguished from the second bonding contact 213 formed in the form of a contact or hole. The first bonding wire 216 is connected with the eighth interconnection portion 227 (i.e., the dummy interconnection portion) in the interconnection layer 120 through the first conductive channel 214, so as not to be coupled with the device in the device layer 230. Since a dimension of a single first bonding wire 216 is greater than a dimension of a single second bonding contact 213, the resistance of the metal may be reduced by increasing a trace width of the first bonding wire.

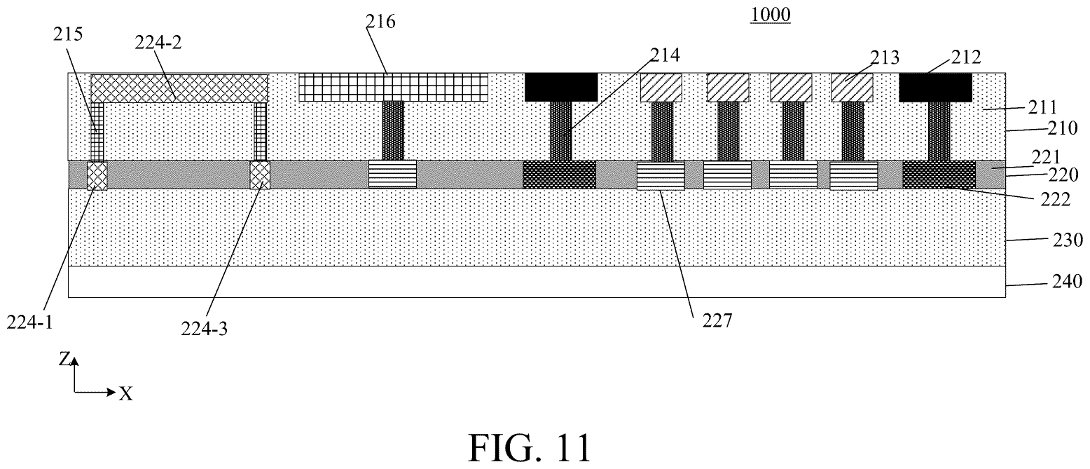

A semiconductor structure 1000 illustrated in the example of FIG. 11 differs from the example of FIG. 10 in that, the third interconnection portion in the bonding layer 210 may be spaced apart from the first bonding contact 212 by at least one first bonding wire 216. The third interconnection portion 224-2 is spaced apart from the first bonding contact 212 by the first bonding wire 216 that is not required to realize an electrical connection function with the device in the device layer 230, so that interference between the third interconnection portion and the first bonding contact may be avoided.

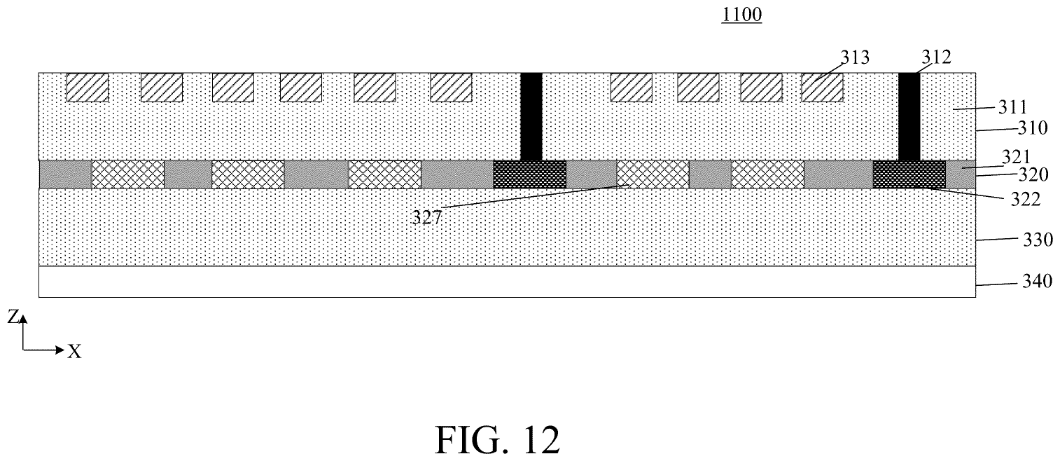

A semiconductor structure 1100 illustrated in the example of FIG. 12 comprises a substrate 340, and a device layer 330, an interconnection layer 320, and a bonding layer 310 stacked sequentially on the substrate 340. The interconnection layer 320 comprises an electrical insulation layer 321 in which seventh interconnection portions 322 and eighth interconnection portions 323 may be arranged at intervals. The bonding layer 310 comprises a dielectric layer 311 in which first bonding contacts 312 and second bonding contacts 313 may be arranged at intervals. In the example of FIG. 12, the first bonding contact 312 employs a single damascene process, i.e., involves one patterning process (e.g., only one lithography and development process). That is, the first conductive channel described above is not required to be additionally formed, whereas the first bonding contact 312 is connected with the seventh interconnection portion 322, thereby simplifying the fabrication process of the first bonding contact and reducing the process cost.

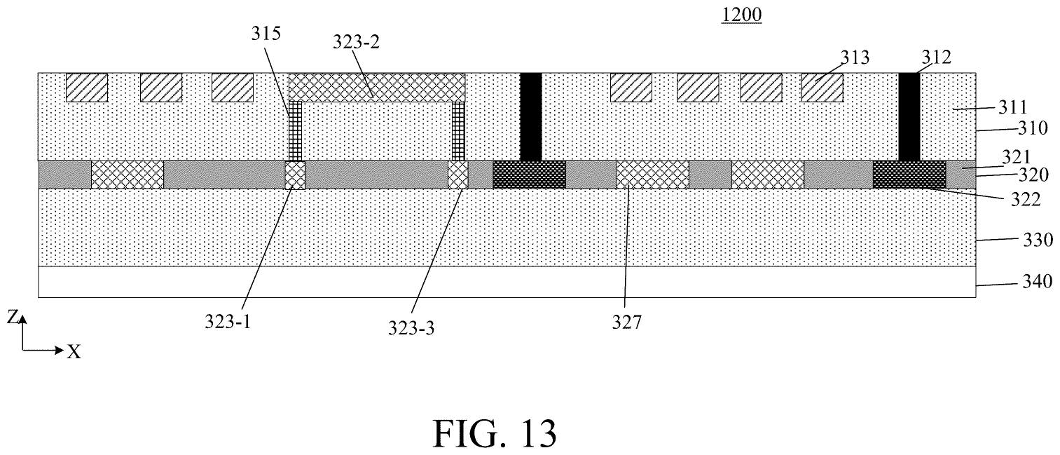

A semiconductor structure 1200 provided in FIG. 13 differs from the example of FIG. 12 in that, the interconnection layer 320 further comprises a first interconnection portion 323-1 and a second interconnection portion 323-3. The bonding layer 310 further comprises a third interconnection portion 323-2. The third interconnection portion 323-2 is connected with the first interconnection portion 323-1 and the second interconnection portion 323-3 respectively through a second conductive channel 315. On the one hand, disposing the second part of at least parts of the interconnection portions in the bonding layer can reduce the cost. On the other hand, forming the first bonding contact through the single damascene process can simplify the fabrication process of the first bonding contact and reduce the process cost.

In the example of FIG. 13, when the second part of at least parts of the interconnection portions is added in the bonding layer 310, the second bonding contact 313 included in the bonding layer 310 may still remain in the form of a contact or a hole, thereby allowing compatibility with the original fabrication process and reducing the complexity of the fabrication process.

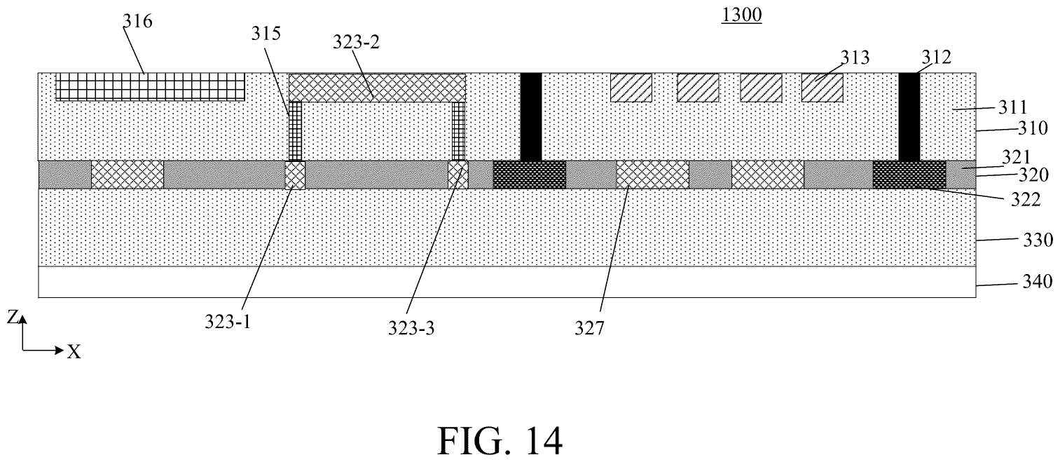

A semiconductor structure 1300 illustrated in the example of FIG. 14 differs from the example of FIG. 13 in that, when the second part of at least parts of the interconnection portions is added in the bonding layer 310, at least parts of second bonding contacts 313 included in the bonding layer 310 may be formed integrally using a conductive material, such as metal, here referred to as a first bonding wire 316, so as to be distinguished from the second bonding contact 313 formed in the form of a contact or hole. The first bonding wire 316 is not connected with the eighth interconnection portion 327 in the interconnection layer 320, i.e., not coupled with the device in the device layer 330. Since a dimension of a single first bonding wire 316 is greater than a dimension of a single second bonding contact 313, the resistance of the metal may be reduced by increasing a trace width of the first bonding wire.

In some examples, the third interconnection portion 323-2 in the bonding layer 310 may be spaced apart from the first bonding contact 312 by at least one second bonding contact 313 or at least one first bonding wire 316, so that interference between the third interconnection portion and the first bonding contact may be avoided. In some other examples, the second bonding contact 313 or the first bonding wire 316 may be connected with a dummy interconnection portion (e.g., the eighth interconnection portion 327) in the interconnection layer 320 that is not electrically connected with the device in the device layer 320.

An example of the present disclosure further provide a semiconductor device comprising a first semiconductor structure and a second semiconductor structure. The first semiconductor structure comprises a first interconnection layer and a first bonding layer. The first semiconductor structure may be a semiconductor structure in any of the examples of FIG. 1 to FIG. 14 above. The first interconnection layer comprises a first interconnection portion and a second interconnection portion. The first bonding layer comprises a first bonding portion and a third interconnection portion. The first interconnection portion is connected with the second interconnection portion through the third interconnection portion. The second semiconductor structure comprises a second interconnection layer. A second bonding layer comprises a second bonding portion. The first bonding portion is coupled with the second bonding portion.

In the semiconductor device provided by the example of the present disclosure, one part of at least one interconnection portion of the first semiconductor structure is disposed in the first interconnection layer and the other part is disposed in the first bonding layer, so that the number of routing layers in the first interconnection layer may be reduced, thereby reducing the cost.

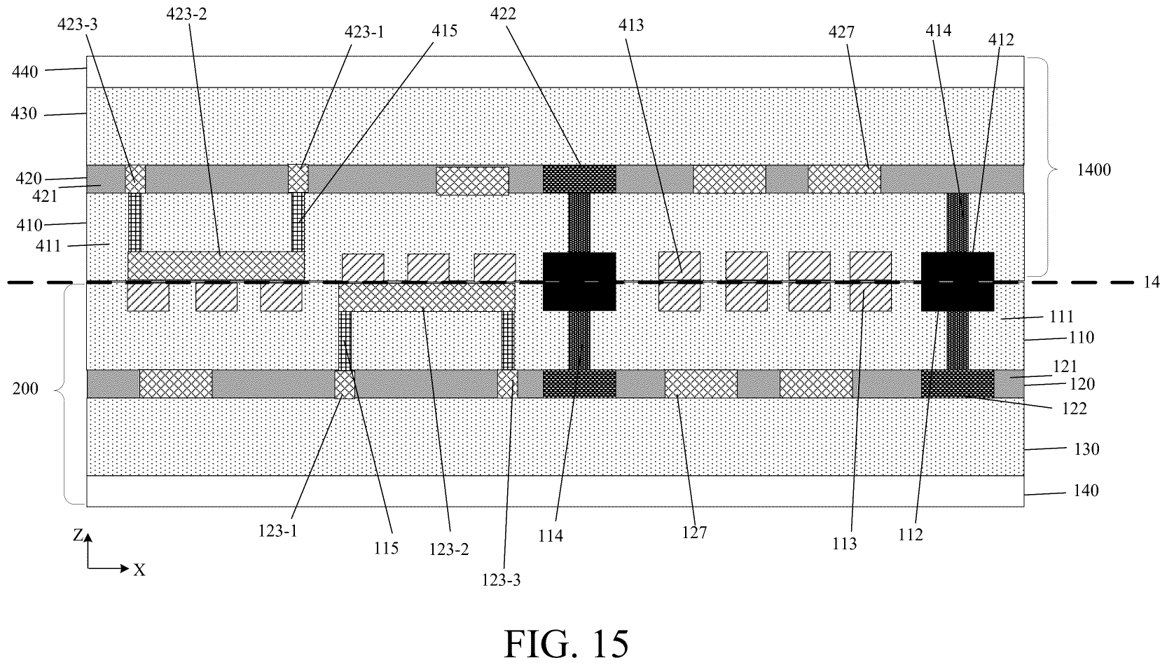

As shown in FIG. 15, the semiconductor device provided by the example of the present disclosure comprises the first semiconductor structure 200 and a second semiconductor structure 1400.

The semiconductor structure 200 comprises a first substrate 140, and a first device layer 130, the first interconnection layer 120, and the first bonding layer 110 stacked sequentially on the first substrate 140. The first interconnection layer 120 may comprise a first electrical insulation layer 121, and the seventh interconnection portion 122 and the eighth interconnection portion 127 are disposed in the first electrical insulation layer 121. The first bonding layer 110 may comprise a first dielectric layer 111, and the first bonding contact 112 and the second bonding contact 113 are disposed in the first dielectric layer 111. The first bonding contact 112 is connected with the seventh interconnection portion 122 in the first interconnection layer 120 through the first conductive channel 114, so as to realize coupling with a first device in the first device layer 130. There is no conductive channel that connects the second bonding contact 113 with the eighth interconnection portion 127, and the second bonding contact 113 therefore is not coupled with the first device in the first device layer 130. In the example of FIG. 15, the first interconnection layer 120 further comprises the first interconnection portion 123-1 and the second interconnection portion 123-3, and the first bonding layer 110 further comprises the third interconnection portion 123-2. The third interconnection portion 123-2 may be coupled with the first interconnection portion 123-1 and the second interconnection portion 123-2 in the first interconnection layer 120 respectively through the second conductive channel 115. That is, at least one interconnection portion comprises two parts, with one of the two parts included in the interconnection portion that is disposed in the first interconnection layer 120 being referred to as a first part of the interconnection portion, and the other one of the two parts that is disposed in the first bonding layer 110 being referred to as a second part of the interconnection portion.

In the examples of the present disclosure, a region in the first bonding layer 110 that is used to disposed the first bonding contact 112 in the first bonding portion is referred to as a first region, and the other region is referred to as a second region. In the examples of the present disclosure, the third interconnection portion is disposed in a region in the first bonding layer that is not used to arrange the first bonding contact having an electrical connection function, so as to reduce the number of routing layers of the interconnection portions in the first interconnection layer, without affecting the distribution of the first bonding contacts in the first bonding layer.

With continued reference to FIG. 15, a part of the routings (jumping wires) that cannot be completely laid out in the topmost metal layer inside the first semiconductor structure 200 (e.g., CMOS or array wafer) may be routed to the first bonding layer 110 through the second conductive channel 115 to form the third interconnection portion 123-2, and then goes downward after reaching the destination electrical connection point, so as to be connected with the second interconnection portion 123-3 through the second conductive channel 115. As such, an actual metal connection relationship within the first semiconductor structure 200 may be unaffected, and just a part of the metal routings are routed into the first bonding layer 110, so as avoid providing an additional metal layer in the first interconnection layer 120.

In the example of FIG. 15, when the second part of at least parts of the interconnection portions is added in the first bonding layer 110, the second bonding contact 113 included in the first bonding layer 110 may still remain in the form of a contact or a hole, thereby allowing compatibility with the original fabrication process and reducing the complexity of the fabrication process.

The first semiconductor structure 200 shown in FIG. 15 is not limited to the CMOS or array wafer, but may be fabricated into any wafer, as long as it utilizes at least one of the blank region or the position(s) of the original dummy hole(s) in the bonding layer to lay out the metal trace inside the wafer.

In the example of FIG. 15, the first bonding contact 112 and the first conductive channel 114 employ a dual damascene process, i.e., involve two patterning processes (e.g., two lithography and development processes), so as to increase a bonding yield. Meanwhile, by implementing a reasonable distribution of the first bonding contact 112, the second bonding contact 113, and the third interconnection portion 123-2 in the bonding layer, the required uniformity of metal and dielectric distribution can be achieved, so that non-uniformity of corrosion control and recess control of the device during a subsequent chemical mechanical polishing (CMP) process can be avoided.

In an example, the first device included in the first device layer 130 is a memory device or a peripheral device.

In some examples, the first semiconductor structure 200 is a peripheral device chip or a memory array device chip, and the first device layer 130 comprises a peripheral device or a NAND memory string.

The second semiconductor structure 1400 comprises a second substrate 440, and a second device layer 430, a second interconnection layer 420, and a second bonding layer 410 stacked sequentially below the second substrate 440. The second interconnection layer 420 may comprise a second electrical insulation layer 421, and a ninth interconnection portion 422 and a tenth interconnection portion 427 are disposed in the second electrical insulation layer 421. The second bonding layer 410 may comprise a second dielectric layer 411, and a third bonding contact 412 and a fourth bonding contact 413 are disposed in the second dielectric layer 411. The third bonding contact 412 is connected with the ninth interconnection portion 422 in the second interconnection layer 420 through a third conductive channel 414, so as to realize coupling with a second device in the second device layer 430. There is no conductive channel that connects the fourth bonding contact 413 with the tenth interconnection portion 427, and the fourth bonding contact 413 therefore is not coupled with the second device in the second device layer 430.

In the example of FIG. 15, the second interconnection layer 420 further comprises a fourth interconnection portion 423-1 and a fifth interconnection portion 423-3, and the second bonding layer 410 further comprises a sixth interconnection portion 423-2. The sixth interconnection portion 423-2 in the second bonding layer 410 may be connected with the fourth interconnection portion 423-1 and the fifth interconnection portion 423-3 in the second interconnection layer 420 respectively through a fourth conductive channel 415.

In the examples of the present disclosure, a region in the second bonding layer 410 that is used to disposed the third bonding contact of the second bonding portion is referred to as a first region, and the other region is referred to as a second region. The sixth interconnection portion is disposed in the second region. In some examples, the fourth bonding contact may be also arranged in the second region. In the examples of the present disclosure, at least parts of the interconnection portions in the second semiconductor structure are disposed in a region in the second bonding layer that is not used to arrange the third bonding contact having an electrical connection function, so as to reduce the number of routing layers of the interconnection portions in the second interconnection layer, without affecting the distribution of third bonding contacts in the second bonding layer.

In the example of FIG. 15, when the second part of at least parts of the interconnection portions is added in the second bonding layer 410, the fourth bonding contact 413 included in the second bonding layer 410 may still remain in the form of a contact or a hole, thereby allowing compatibility with the original fabrication process and reducing the complexity of the fabrication process.

The second semiconductor structure 1400 shown in FIG. 15 is not limited to the array or CMOS wafer, but may be fabricated into any wafer, as long as it utilizes at least one of the blank region or the position(s) of the original dummy hole(s) in the bonding layer to lay out the metal trace inside the wafer.

In the example of FIG. 15, the second bonding contact 412 and the first conductive channel 414 employ a dual damascene process, i.e., involve two patterning processes (e.g., two lithography and development processes), so as to increase a bonding yield. Meanwhile, by implementing a reasonable distribution of the third bonding contact 412, the fourth bonding contact 413, and the sixth interconnection portion 423-2 in the second bonding layer 410, the required uniformity of metal and dielectric distribution can be achieved, so that non-uniformity of corrosion control and recess control of the device during a subsequent chemical mechanical polishing (CMP) process can be avoided.

In an example, the second device included in the second device layer 430 is a peripheral device or a memory device.

In some examples, the second semiconductor structure 1400 is a memory array device chip or a peripheral device chip, and the second device layer 430 comprises a NAND memory string or a peripheral device.

With continued reference to FIG. 15, the semiconductor device may further comprise a bonding interface 14 between the first semiconductor structure 200 and the second semiconductor structure 1400. It is to be understood that the semiconductor device may include any other suitable semiconductor devices of a 2D, 2.5D, or 3D architecture, such as a logic device, a volatile memory device, and a non-volatile memory device.

In the example of FIG. 15, on opposite sides of the bonding interface 14, the first bonding contact 112 is coupled with the third bonding contact 412 to implement electrical coupling between the first semiconductor structure 200 and the second semiconductor structure 1400. Each of at least parts of the second bonding contacts 113 is coupled with the corresponding fourth bonding contact 413 respectively, and is not a part of an electrical connection crossing the bonding interface 14 and between the first semiconductor structure 200 and the second semiconductor structure 1400. As such, the bonding strength and reliability can be improved, thereby increasing a product yield.

In the example of FIG. 15, the third interconnection portion 123-2 is coupled with at least parts of the fourth bonding contacts 413, with the fourth bonding contacts 413 being dummy bonding contacts, so that an unnecessary electrical connection between the interconnection portion in the first semiconductor structure 200 and the second device in the second semiconductor structure 1400 can be avoided. In other examples, the third interconnection portion 123-2 may not contact the fourth bonding contact 413, that is, the third interconnection portion 123-2 may only contact at least a part of the surface of the second dielectric layer 411 in the second semiconductor structure 1400.

In the example of FIG. 15, the sixth interconnection portion 423-2 is coupled with at least parts of the second bonding contacts 113, so that an unnecessary electrical connection between the interconnection portion in the second semiconductor structure 1400 and the first device in the first semiconductor structure 200 can be avoided. In other examples, the sixth interconnection portion 423-2 may not contact the second bonding contact 113, that is, the sixth interconnection portion 423-2 may only contact at least a part of the surface of the first dielectric layer 111 in the first semiconductor structure 200.

Such a manner in FIG. 15 may be referred to as Dummy Via Bond Metal.

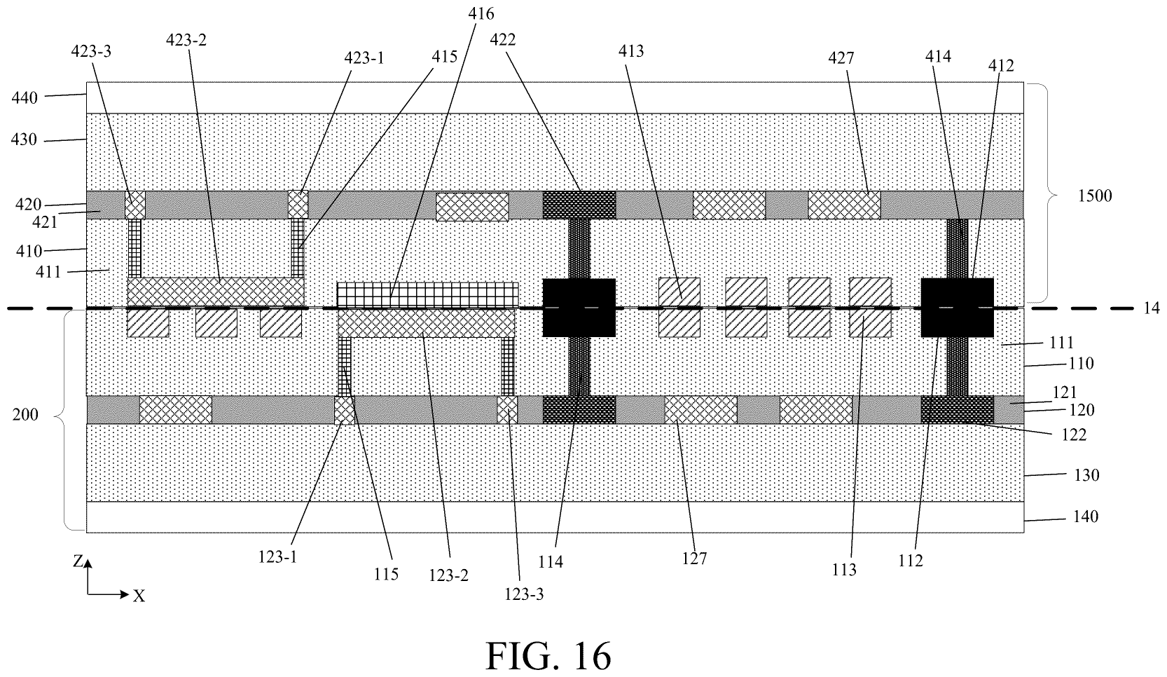

A semiconductor device shown FIG. 16 differs from the example of FIG. 15 in that, at least parts of the fourth bonding contacts 413 included in the second bonding layer 410 in a second semiconductor structure 1500 may be formed integrally using a conductive material, such as metal, here referred to as a second bonding wire 416, so as to be distinguished from the fourth bonding contact 413 formed in the form of a contact or hole. The second bonding wire 416 is not connected with the tenth interconnection portion 427 in the second interconnection layer 420, and thus is not coupled with the second device in the second device layer 430. Since a dimension of a single second bonding wire 416 is greater than a dimension of a single fourth bonding contact 413, the resistance of the metal may be reduced by increasing a trace width of the second bonding wire.

In the example of FIG. 16, the third interconnection portion 123-2 is coupled with the second bonding wire 416, so that an unnecessary electrical connection between the interconnection portion in the first semiconductor structure 200 and the second device in the second semiconductor structure 1500 can be avoided. Such a manner in FIG. 16 may be referred to as Dummy Metal bond Metal.

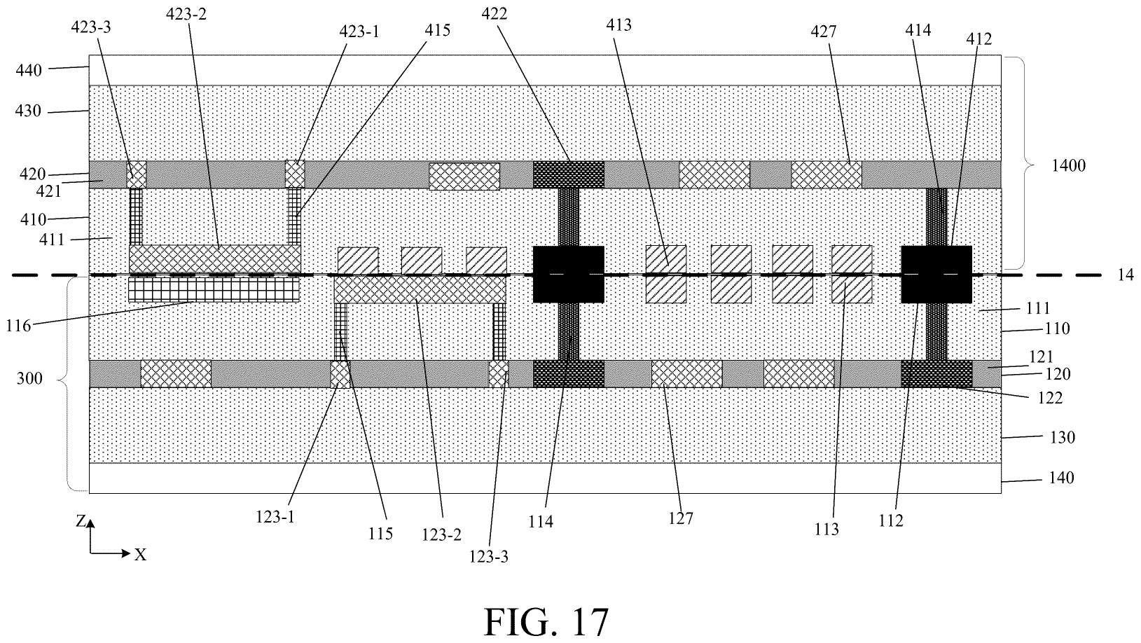

The semiconductor device illustrated in the example of FIG. 17 differs from that illustrated in FIG. 15 in that, at least parts of the second bonding contacts 113 included in the first bonding layer 110 in the first semiconductor structure 300 may be formed integrally using a conductive material, such as metal, here referred to as the first bonding wire 116. The first bonding wire 116 is not connected with the eighth interconnection portion 127 in the first interconnection layer 120, and thus is not coupled with the first device in the first device layer 130. Since a dimension of a single first bonding wire 116 is greater than a dimension of a single second bonding contact 113, the resistance of the metal may be reduced by increasing a trace width of the first bonding wire.

In the example of FIG. 17, the sixth interconnection portion 423-2 is coupled with the first bonding wire 116, so that an unnecessary electrical connection between the interconnection portion in the second semiconductor structure 1400 and the first device in the first semiconductor structure 300 can be avoided.

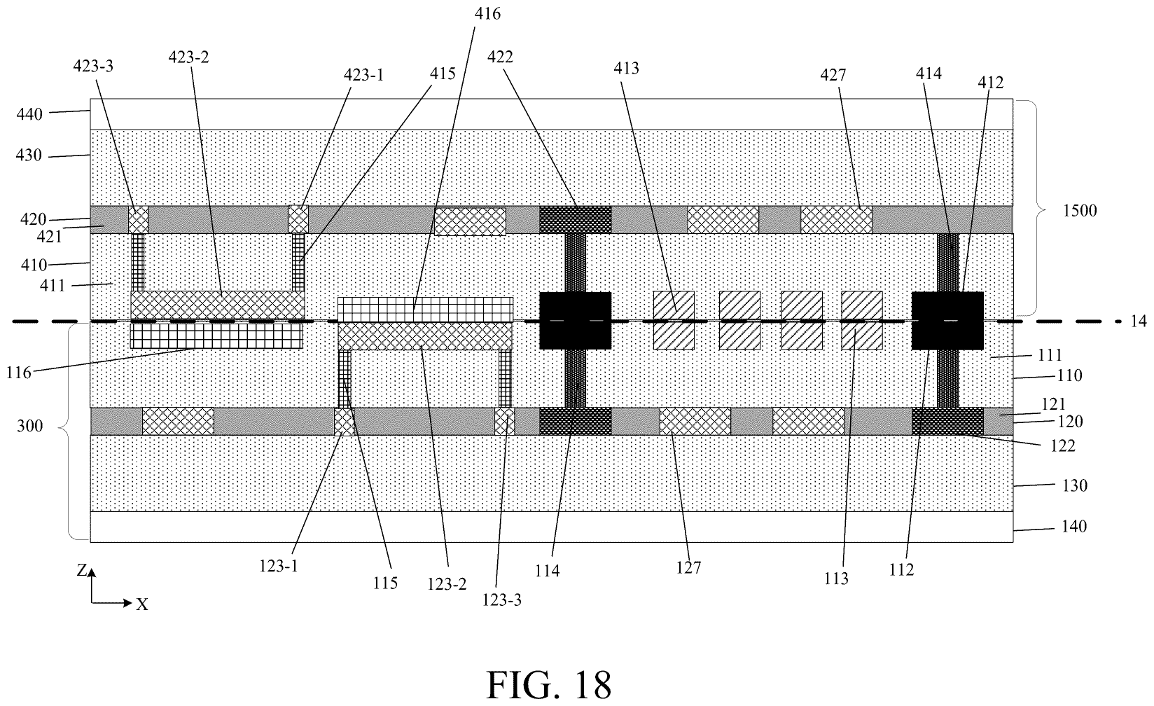

The example of FIG. 18 differs from the example of FIG. 17 in that, at least parts of the fourth bonding contacts 413 included in the second bonding layer 410 in the second semiconductor structure 1500 may be formed integrally using a conductive material, such as metal, here referred to as the second bonding wire 416. As such, the resistance of the metal may be reduced by increasing a trace width of the second bonding wire. The third interconnection portion 123-2 is coupled with the second bonding wire 416, so that an unnecessary electrical connection between the interconnection portion in the first semiconductor structure 200 and the second device in the second semiconductor structure 1500 can be avoided.

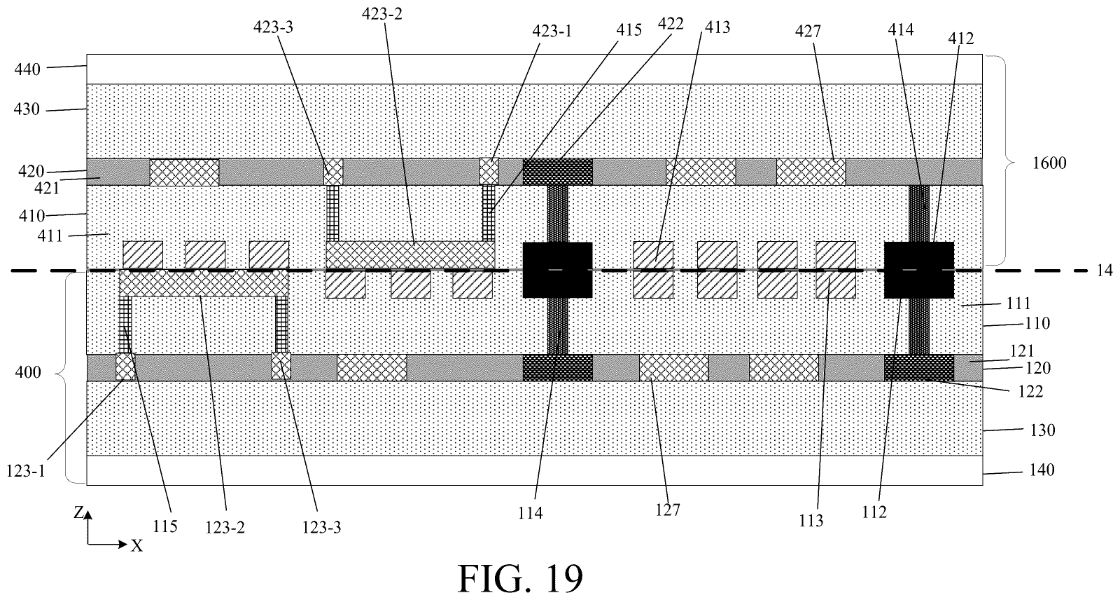

The semiconductor device illustrated in the example of FIG. 19 differs from the example of FIG. 15 in that, the fourth interconnection portion 423-1, the fifth interconnection portion 423-3, and the sixth interconnection portion 423-2 in a second semiconductor structure 1600 are positionally interchanged with the fourth bonding contacts 413. Correspondingly, the first interconnection portion 123-1, the second interconnection portion 123-3, and the third interconnection portion 123-2 in the first semiconductor structure 400 are positionally interchanged with the second bonding contacts 113.

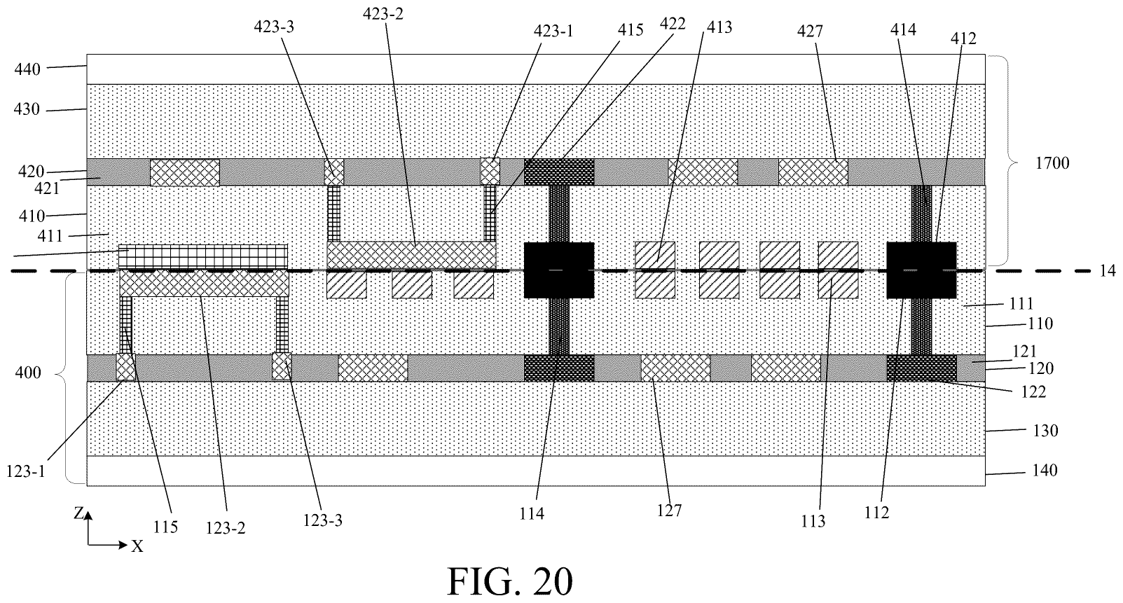

The semiconductor device illustrated in the example of FIG. 20 differs from that illustrated in FIG. 19 in that, at least parts of the fourth bonding contacts 413 included in the second bonding layer 410 in a second semiconductor structure 1700 may be formed integrally using a conductive material, such as metal, here referred to as the first bonding wire 416. The first bonding wire 416 is not connected with the tenth interconnection portion 427 in the second interconnection layer 420, i.e., not coupled with the second device in the second device layer 430. The third interconnection portion 123-2 is coupled with the second bonding wire 416.

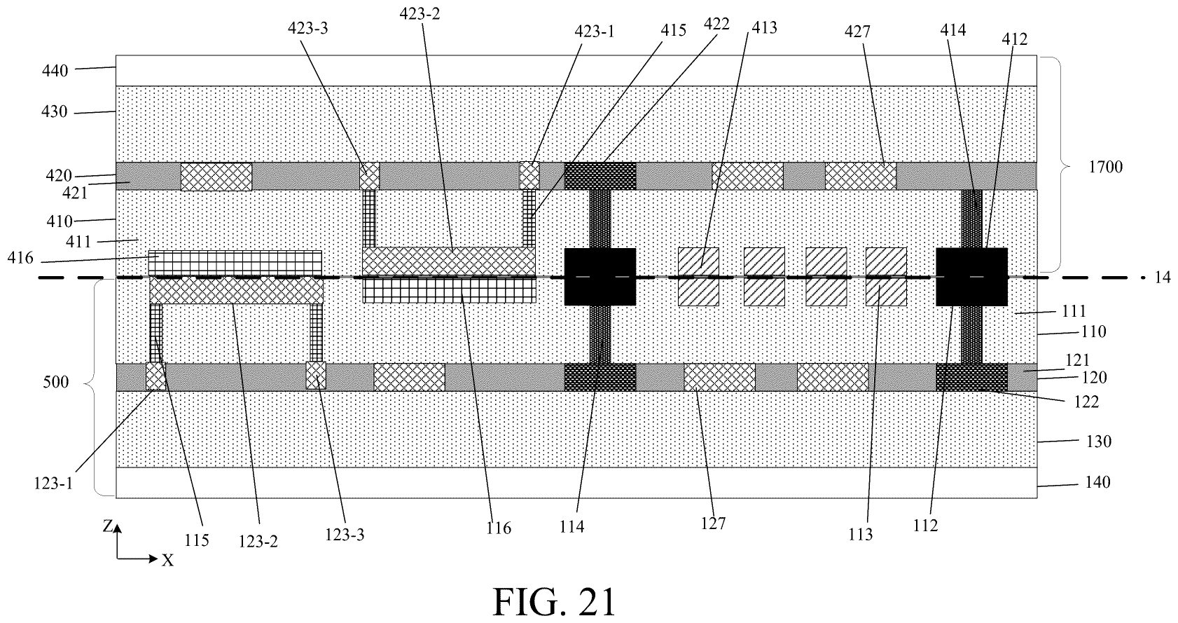

The semiconductor devices provided by the examples of FIG. 21 and FIG. 20 differ in that, at least parts of the second bonding contacts 113 included in the first bonding layer 110 in the first semiconductor structure 500 may be formed integrally using a conductive material, such as metal, here referred to as the first bonding wire 116. The first bonding wire 116 is not connected with the eighth interconnection portion 127 in the first interconnection layer 120, i.e., not coupled with the first device in the first device layer 130. The sixth interconnection portion 423-2 is coupled with the first bonding wire 116.

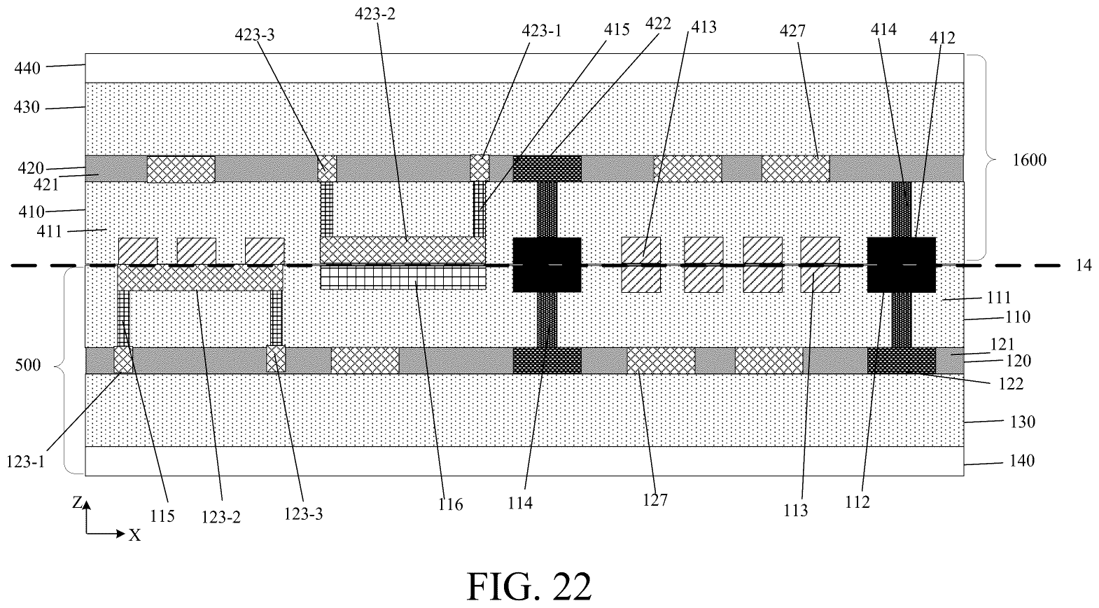

The semiconductor devices provided by the examples of FIG. 22 and FIG. 21 differ in that, in the second semiconductor structure 1600, the second bonding contact 413 is coupled with the third interconnection portion 123-2.

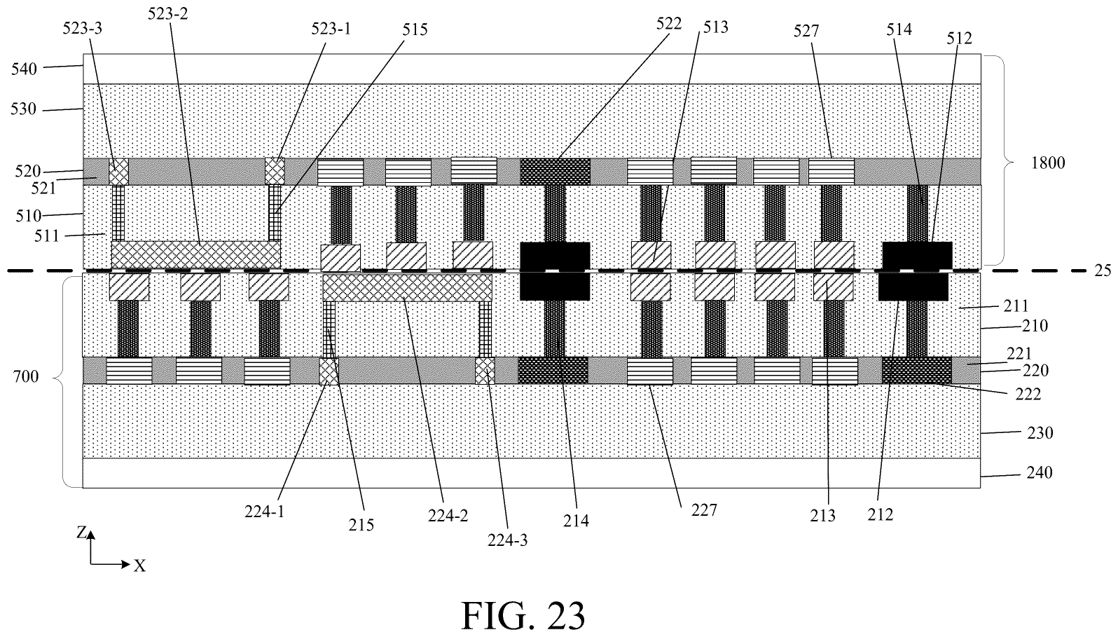

A semiconductor device illustrated in FIG. 23 comprises the first semiconductor structure 700 and a second semiconductor structure 1800. The first semiconductor structure 700 comprises the first substrate 240, and the first device layer 230, the first interconnection layer 220, and the first bonding layer 210 stacked sequentially on the first substrate 240. The first interconnection layer 220 comprises the first electrical insulation layer 221 in which the seventh interconnection portions 222 and the eighth interconnection portions 227 may be arranged at intervals. The first bonding layer 210 comprises the first dielectric layer 211 in which the first bonding contacts 212 and the second bonding contacts 213 may be arranged at intervals. The first bonding contact 212 and the second bonding contact 213 both may be electrically connected with the seventh interconnection portion 222 and the eighth interconnection portion 227 in the first interconnection layer 220 respectively through the first conductive channel 214. The seventh interconnection portion 222 is electrically connected with the first device in the first device layer 230, and the seventh interconnection portion 222 therefore may be referred to as a functional interconnection portion. The eighth interconnection portion 227 is not electrically connected with the first device in the first device layer 230, and therefore may be referred to as a dummy interconnection portion. Forming the first bonding contact and the second bonding contact through the same process can simplify a fabrication process of the first bonding portion. Meanwhile, an electrical connection between the first bonding contact and the first device in the first device layer can be implemented, whereas the second bonding contact is not electrically connected with the first device in the first device layer.

The first interconnection layer 220 further comprises the first interconnection portion 224-1 and the second interconnection portion 224-3. The first bonding layer 210 further comprises the third interconnection portion 224-2. The third interconnection portion 224-2 is connected with the first interconnection portion 224-1 and the second interconnection portion 224-3 respectively through the second conductive channel 215. On the one hand, disposing the second part of at least parts of the interconnection portions in the first bonding layer may reduce the cost. On the other hand, forming the first bonding contact and the second bonding contact through the same process can simplify a fabrication process of the first bonding portion. Meanwhile, an electrical connection between the first bonding contact and the first device in the first device layer can be implemented, whereas the second bonding contact is not electrically connected with the first device in the first device layer.

When the second part of at least parts of the interconnection portions is added in the first bonding layer 210, the second bonding contact 213 included in the first bonding layer 210 may still remain in the form of a contact or a hole, thereby allowing compatibility with the original fabrication process and reducing the complexity of the fabrication process.

The second semiconductor structure 1800 comprises a second substrate 540, and a second device layer 530, a second interconnection layer 520, and a second bonding layer 510 stacked sequentially below the second substrate 540. The second interconnection layer 520 comprises a second electrical insulation layer 521 in which ninth interconnection portions 522 and tenth interconnection portions 527 may be arranged at intervals. The second bonding layer 510 comprises a second dielectric layer 511 in which third bonding contacts 512 and fourth bonding contacts 513 may be arranged at intervals. The third bonding contact 512 and the fourth bonding contact 513 both may be electrically connected with the ninth interconnection portion 522 and the tenth interconnection portion 527 in the second interconnection layer 520 respectively through the third conductive channel 514. The ninth interconnection portion 522 is electrically connected with a second device in the second device layer 530, and the ninth interconnection portion 522 therefore may be referred to as a functional interconnection portion. The tenth interconnection portion 527 is not electrically connected with the second device in the second device layer 530, and therefore may be referred to as a dummy interconnection portion. Forming the third bonding contact and the second bonding contact through the same process can simplify a fabrication process of the second bonding portion. Meanwhile, an electrical connection between the third bonding contact and the second device in the second device layer can be implemented, whereas the fourth bonding contact is not electrically connected with the second device in the second device layer.

The second interconnection layer 520 further comprises a fourth interconnection portion 523-1 and a fifth interconnection portion 523-3. The second bonding layer 510 further comprises a sixth interconnection portion 523-2. The sixth interconnection portion 523-2 is electrically connected with the fourth interconnection portion 523-1 and the fifth interconnection portion 523-3 respectively through a fourth conductive channel 515. When the second part of at least parts of the interconnection portions is added in the second bonding layer 510, the fourth bonding contact 513 included in the second bonding layer 510 may still remain in the form of a contact or a hole, thereby allowing compatibility with the original fabrication process and reducing the complexity of the fabrication process.

In the example of FIG. 23, the third interconnection portion 224-2 is coupled with at least parts of the fourth bonding contacts 513. The sixth interconnection portion 523-2 is coupled with at least parts of the second bonding contacts 223. A bonding interface 25 is present after the first semiconductor structure 700 and the second semiconductor structure 1800 are bonded.

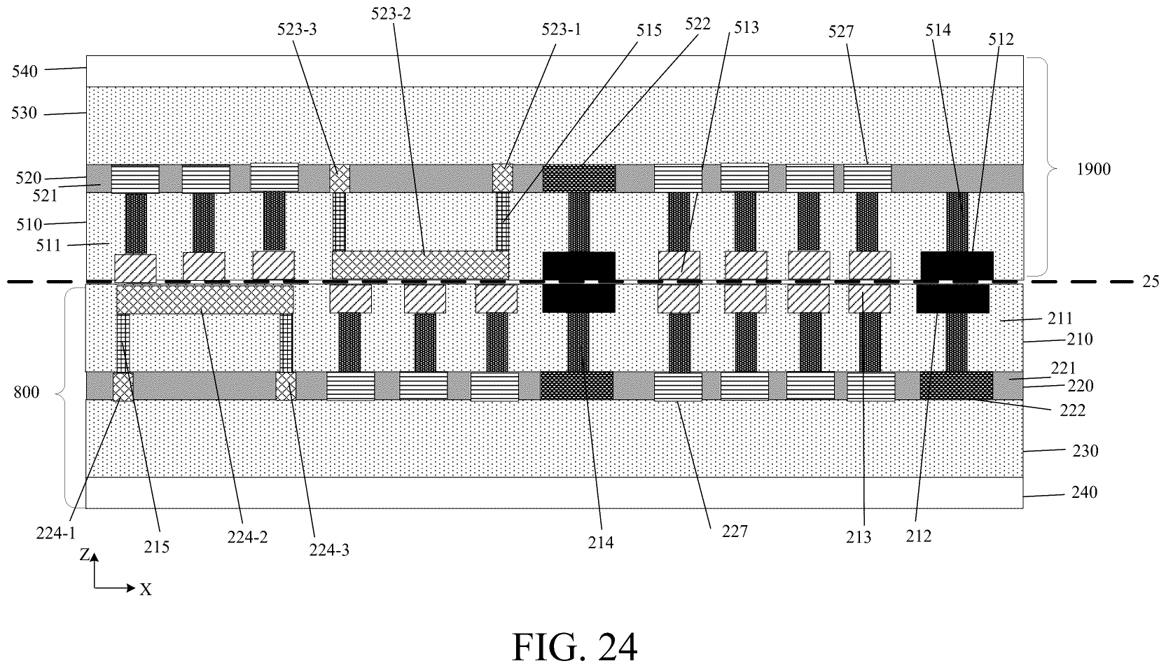

The semiconductor device illustrated in FIG. 24 differs from that illustrated in FIG. 23 in that, the first interconnection portion 224-1, the second interconnection portion 224-3, and the third interconnection portion 224-2 included in the first semiconductor structure 800 are positionally interchanged with at least parts of the second bonding contacts 213. Correspondingly, the fourth interconnection portion 523-1, the fifth interconnection portion 523-3, and the sixth interconnection portion 523-2 in a second semiconductor structure 1900 are positionally interchanged with at least parts of the fourth bonding contacts 513.

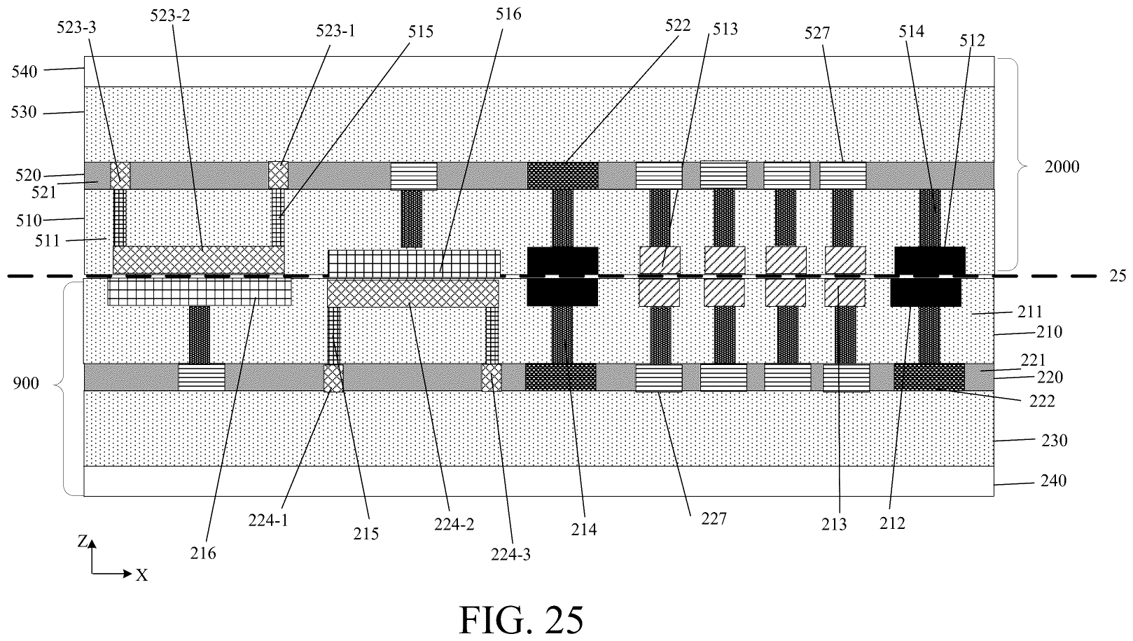

The semiconductor device illustrated in FIG. 25 differs from that illustrated in FIG. 23 in that, the first semiconductor structure 900 comprises the first bonding wire 216, and the first bonding wire 216 is coupled with the sixth interconnection portion 523-2 in a second semiconductor structure 2000. The first bonding wire 216 is coupled with the eighth interconnection portion 227 through the first conductive channel 214, wherein the eighth interconnection portion 227 is a dummy interconnection portion. The second semiconductor structure 2000 comprises the second bonding wire 516, which is coupled with the third interconnection portion 224-2 in the first semiconductor structure 900. The second bonding wire 516 is coupled with the tenth interconnection portion 527 through the third conductive channel 514, wherein the tenth interconnection portion 527 is a dummy interconnection portion.

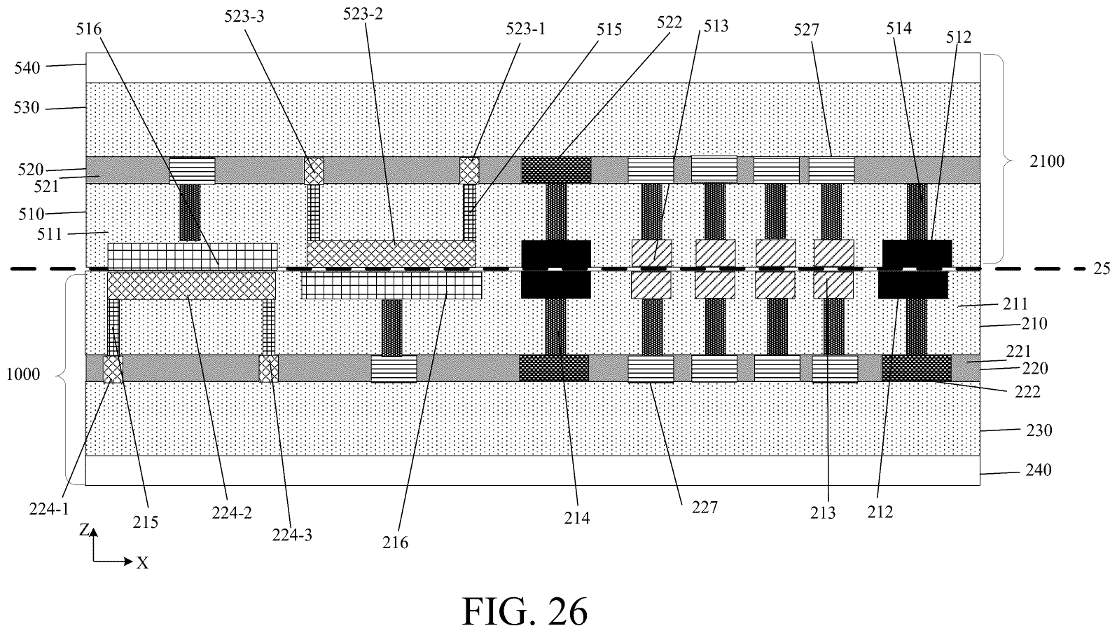

The semiconductor device illustrated in FIG. 26 differs from that illustrated in FIG. 25 in that, the first bonding wire 216 in the first semiconductor structure 1000 is positionally interchanged with the first interconnection portion 224-1, the second interconnection portion 224-3, and the third interconnection portion 224-2. Correspondingly, the second bonding wire 516 in a second semiconductor structure 2100 is positionally interchanged with the fourth interconnection portion 523-1, the fifth interconnection portion 523-3, and the sixth interconnection portion 523-2.

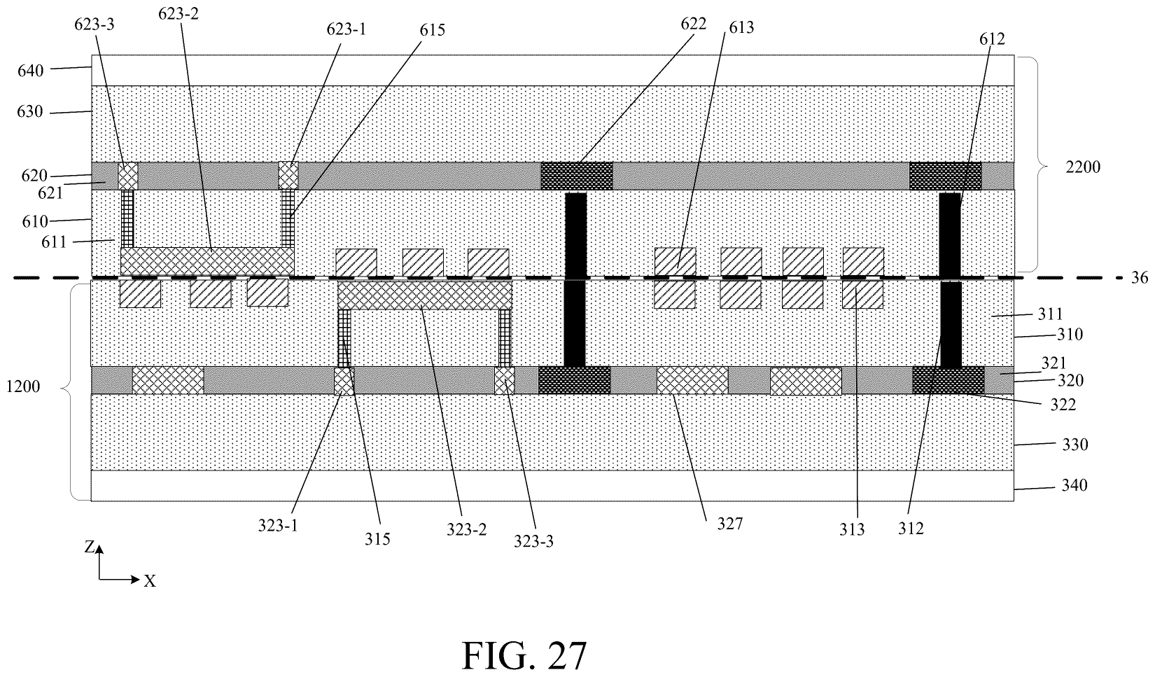

As shown in FIG. 27, the semiconductor device provided by the example of the present disclosure comprises a first semiconductor structure 1200 and a second semiconductor structure 2200.

The first semiconductor structure 1200 comprises the first substrate 340, and the first device layer 330, the first interconnection layer 320, and the first bonding layer 310 stacked sequentially on the first substrate 340. The first interconnection layer 320 may comprise the first electrical insulation layer 321, and the seventh interconnection portion 322 and the eighth interconnection portion 327 are disposed in the first electrical insulation layer 321. The first bonding layer 310 may comprise the first dielectric layer 311, and the first bonding contact 312 and the second bonding contact 313 are disposed in the first dielectric layer 311. The first bonding contact 312 is formed using a single damascene process and is connected with the seventh interconnection portion 322 in the first interconnection layer 320, so as to realize coupling with the first device in the first device layer 330. The second bonding contact 313 is not connected with the eighth interconnection portion 327, i.e., not coupled with the first device in the first device layer 330. In the example of FIG. 27, at least one interconnection portion comprises two parts, with one of the two parts included in the interconnection portion that is disposed in the first interconnection layer 320 being referred to as a first part of the interconnection portion, and the other one of the two parts that is disposed in the first bonding layer 310 being referred to as a second part of the interconnection portion. A part of the routings (jumping wires) that cannot be completely laid out in the topmost metal layer inside the first semiconductor structure 1200 may be routed to the first bonding layer 310 through the second conductive channel 315 to form the second part of the interconnection portion, and then goes downward after reaching the destination electrical connection point, so as to be connected with the first part of the interconnection portion through the second conductive channel 315.

In the example of FIG. 27, when the second part of at least parts of the interconnection portions is added in the first bonding layer 310, the second bonding contact 313 included in the first bonding layer 310 may still remain in the form of a contact or a hole.

The second semiconductor structure 2200 comprises a second substrate 640, and a second device layer 630, a second interconnection layer 620, and a second bonding layer 610 stacked sequentially below the second substrate 640. The second interconnection layer 620 may comprise a second electrical insulation layer 621, and a ninth interconnection portion 622 is disposed in the second electrical insulation layer 621. The second bonding layer 610 may comprise a second dielectric layer 611, and a third bonding contact 612 and a fourth bonding contact 613 are disposed in the second dielectric layer 611. The third bonding contact 612 is formed using a single damascene process and is connected with the ninth interconnection portion 622 in the second interconnection layer 620, so as to realize coupling with a second device in the second device layer 630. The fourth bonding contact 613 is not coupled with the second device in the second device layer 630.

In the example of FIG. 27, the second interconnection layer 620 further comprises a fourth interconnection portion 623-1 and a fifth interconnection portion 623-3. The second bonding layer 610 further comprises a sixth interconnection portion 623-2. The sixth interconnection portion 623-2 may be connected with the fourth interconnection portion 623-1 and the fifth interconnection portion 623-3 in the second interconnection layer 620 respectively through a fourth conductive channel 615.

In the example of FIG. 27, when the second part of at least parts of the interconnection portions is added in the second bonding layer 610, the fourth bonding contact 613 included in the second bonding layer 610 may still remain in the form of a contact or a hole.

With continued reference to FIG. 27, the semiconductor device may further comprise a bonding interface 36 between the first semiconductor structure 1200 and the second semiconductor structure 2200.

In the example of FIG. 27, on opposite sides of the bonding interface 36, the first bonding contact 312 is coupled with the third bonding contact 612, so as to implement electrical coupling between the first semiconductor structure 1200 and the second semiconductor structure 2200. Each of at least parts of the second bonding contacts 313 is coupled with the corresponding fourth bonding contact 613 respectively, and is not a part of an electrical connection crossing the bonding interface 36 and between the first semiconductor structure 1200 and the second semiconductor structure 2200.

In the example of FIG. 27, the third interconnection portion 323-2 is coupled with at least parts of the fourth bonding contacts 613. The sixth interconnection portion 623-2 is coupled with at least parts of the second bonding contacts 313.

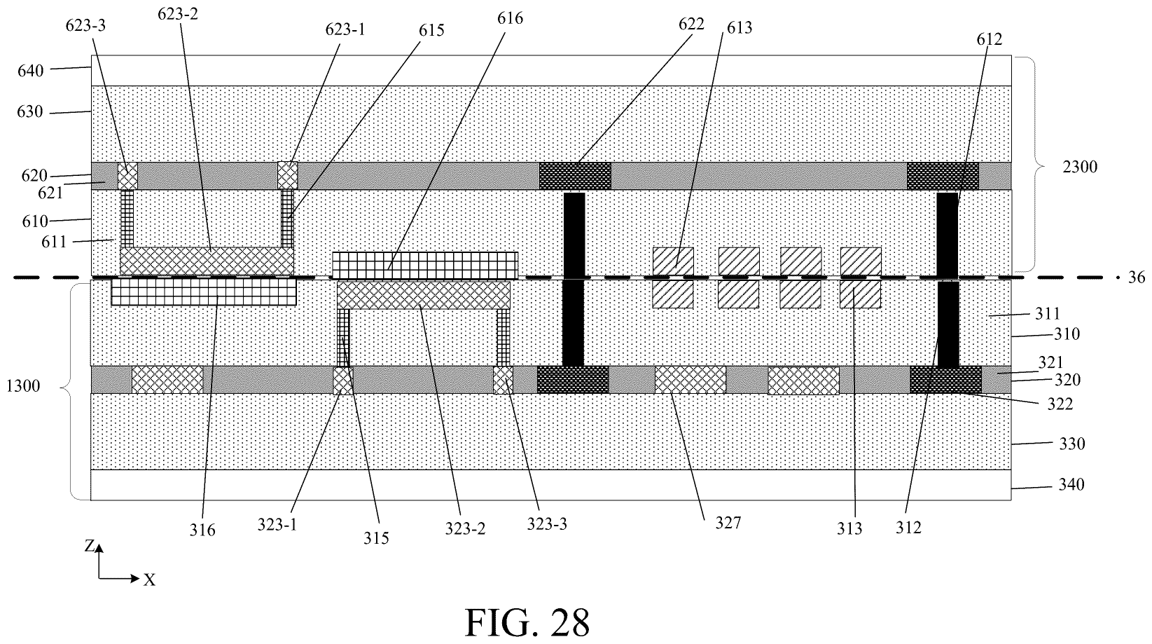

The semiconductor device illustrated in FIG. 28 differs from the example of FIG. 27 in that, the second bonding layer 610 in a second semiconductor structure 2300 comprises a second bonding wire 616, which is coupled with the third interconnection portion 323-2 in a first semiconductor structure 1300. The first bonding layer 310 in the first semiconductor structure 1300 comprises the first bonding wire 316, which is coupled with the sixth interconnection portion 623-2 in the second semiconductor structure 2300. The first bonding wire 316 is not connected with the first interconnection layer. The second bonding wire 616 is not connected with the second interconnection layer.

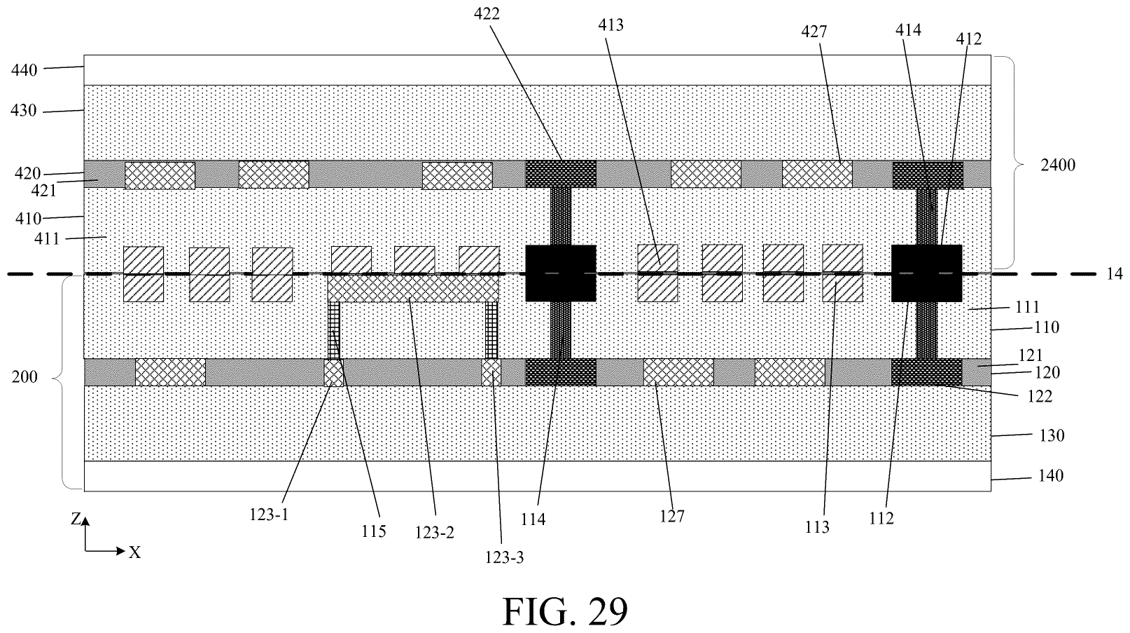

The semiconductor device illustrated in FIG. 29 differs from that illustrated in FIG. 15 in that, no parts of the interconnection portions are arranged in the second bonding layer 410 in a second semiconductor structure 2400.

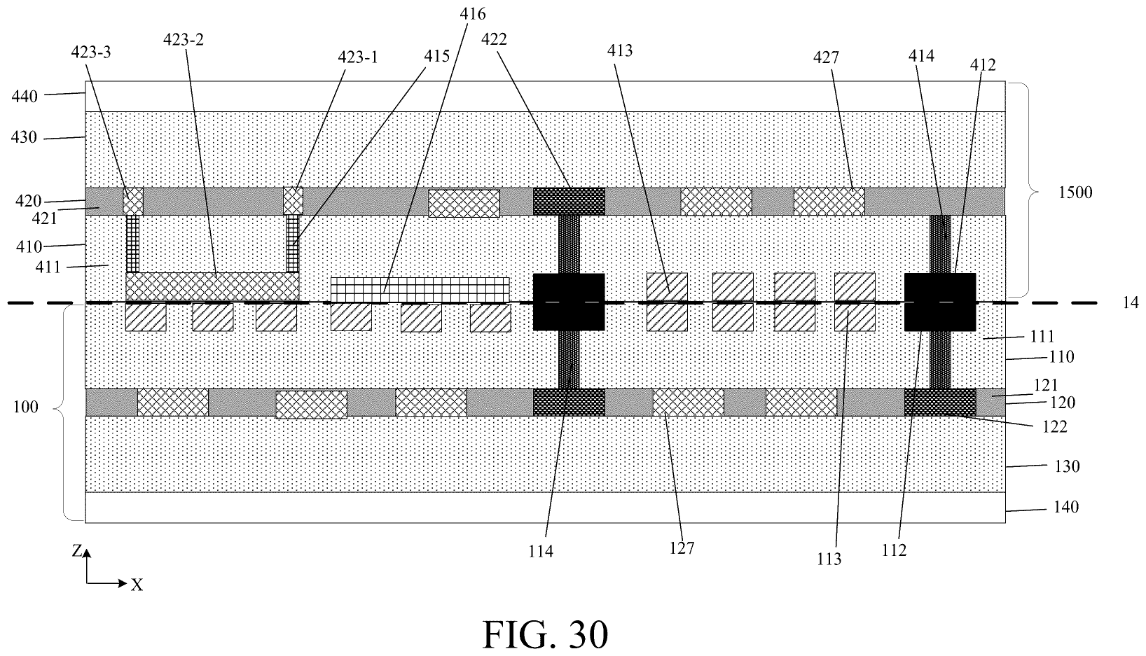

The semiconductor device illustrated in FIG. 30 differs from that illustrated in FIG. 15 in that, no parts of the interconnection portions are arranged in the first bonding layer 110 in the first semiconductor structure 100.

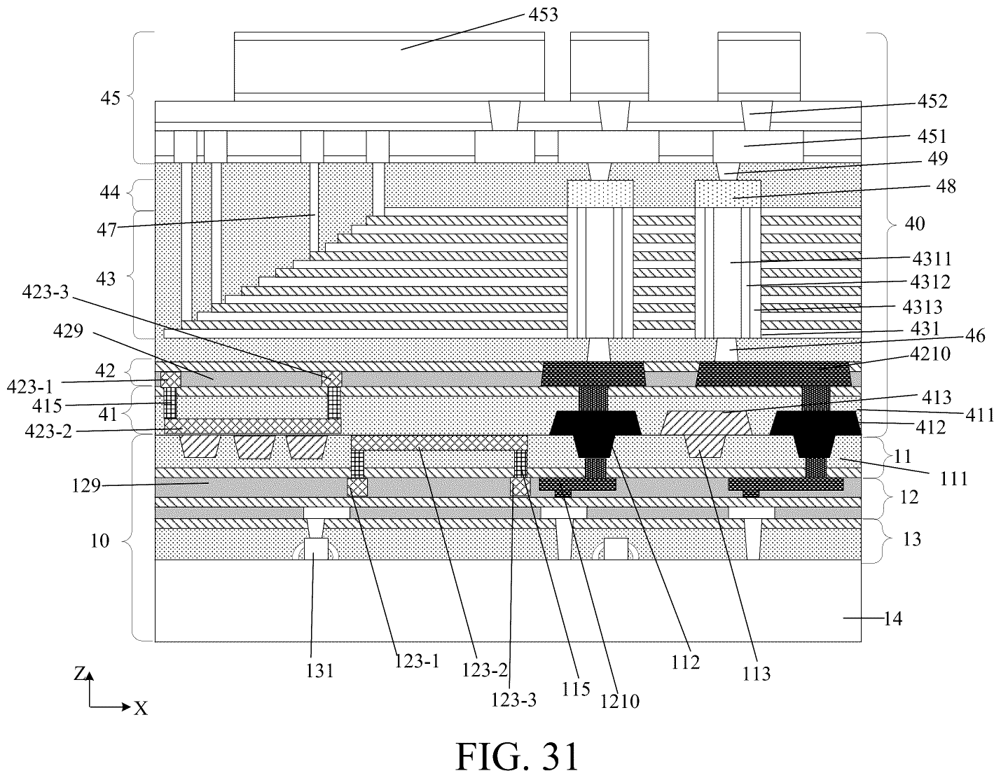

FIG. 31 illustrates a cross section of an example bonded semiconductor device according to some examples of the present disclosure. For ease of description, the bonded semiconductor device is described as a non-monolithic 3D memory device. However, it is to be understood that the bonded semiconductor device is not limited to the 3D memory device and may include any suitable bonded semiconductor device, which may use dummy bonding contacts to improve properties of the bonding interface. It is to be understood that bonded semiconductor device as disclosed herein that comprises dummy bonding contacts at the bonding interface thereof is not limited to the example illustrated in FIG. 31, and may include any other suitable semiconductor devices of a 2D, 2.5D, or 3D architecture, such as a logic device, a volatile memory device (e.g., a dynamic random access memory (DRAM), and a static random access memory (SRAM)), and a non-volatile memory device (e.g., a flash memory).

The bonded semiconductor device represents an example of a non-monolithic 3D memory device. The term “non-monolithic” means that components (e.g., a peripheral device and a memory array device) of the bonded semiconductor device may be formed on different substrates respectively and then bonded to form the bonded semiconductor device. The bonded semiconductor device may comprise a substrate 14, which may include silicon (e.g., monocrystalline silicon), silicon germanium (SiGe), gallium arsenide (GaAs), germanium (Ge), silicon on insulator (SOI), or any other suitable materials.

It is to be noted that FIG. 31 comprises X and Z axes to further illustrate a spatial relationship of the components in the bonded semiconductor device having the substrate 14. The substrate 14 comprises two lateral surfaces (e.g., a top surface and a bottom surface) extending laterally in the X direction (i.e., the lateral direction). As used herein, when the substrate is located in a lowest plane of the semiconductor device in the Z direction (i.e., the vertical direction), one component (e.g., a layer or device) is determined to be “on”, “above”, or “below” another component (e.g., a layer or device) of the semiconductor device (e.g., the bonded semiconductor device) in the Z direction relative to the substrate (e.g., the substrate 14) of the semiconductor device. The same concept used to describe a spatial relationship is applied throughout the present disclosure.

The bonded semiconductor device may comprise two semiconductor structures (which may be referred to as the first semiconductor structure and the second semiconductor structure respectively), i.e., a memory array device chip 40 and a peripheral device chip 10 bonded in a face-to-face manner at a bonding interface. In some examples, the bonding interface is disposed between the memory array device chip 40 and the peripheral device chip 10 due to hybrid bonding (also referred to as “metal/dielectric hybrid bonding”).

The hybrid bonding is a direct bonding technique (e.g., forming bonding between surfaces without using an intermediate layer (e.g., a solder or an adhesive)) and can obtain metal-metal bonding and dielectric-dielectric bonding simultaneously. In some examples, the bonding interface is a position where the memory array device chip 40 meets and is bonded with the peripheral device chip 10. In practice, the bonding interface may be a layer having a certain thickness, and comprises a bottom surface of the memory array device chip 40 and a top surface of the peripheral device chip 10. It is to be understood that, although the memory array device chip 40 is disposed above the peripheral device chip 10 in FIG. 31, the relative position of the memory array device chip 40 and the peripheral device chip 10 may be reversed in some examples. For example, in another bonded semiconductor device, the memory array device chip 40 may be disposed below the peripheral device chip 10.

The peripheral device chip 10 may comprise a peripheral device layer 13 on the substrate 14. The peripheral device layer 13 may comprise a peripheral device (e.g., a plurality of transistors 131) formed on the substrate 14. The transistors 131 may be formed “on” the substrate 14, wherein the entire or a part of each transistor 131 is formed in the substrate 14 (e.g., below a top surface of the substrate 14) and/or directly on the substrate 14. An isolation region (e.g., shallow trench isolation (STI), not shown) and a doped region (e.g., a source region and a drain region of the transistor 131, not shown) may be formed in the substrate 14.

In some examples, the peripheral device of the peripheral device layer 13 may include any suitable digital, analog, and/or mixed signal peripheral circuit for facilitating operations of the bonded semiconductor device. For example, the peripheral device of the peripheral device layer 13 may include one or more of a page buffer, a decoder (e.g., a row decoder and a column decoder), a sensing amplifier, a driver, a charge pump, a current or voltage reference, or any active or passive component (e.g., a transistor, a diode, a resistor, or a capacitor) of a circuit. In some examples, the peripheral device of the peripheral device layer 13 is formed on the substrate 14 using a complementary metal oxide semiconductor (CMOS) technology (also referred to as a “CMOS chip”).

The peripheral device chip 10 may comprise an interconnection layer 12 (herein referred to as a “peripheral interconnection layer” or “first interconnection layer”) above the peripheral device layer 13 for performing electrical signal transmission to and from the peripheral device layer 13. The peripheral interconnection layer 12 may comprise a plurality of interconnection portions 1210, including a lateral interconnection wire and a vertical interconnection access (via hole) contact. As used herein, the term “interconnection” may broadly comprise any suitable type of interconnections, such as a middle-end-of-line (MEOL) interconnection and a back-end-of-line (BEOL) interconnection. As described in detail below, the interconnection portions 1210 in the peripheral interconnection layer 12 may comprise a functional interconnection electrically connected to the peripheral device, and in an example, further comprise a dummy interconnection that is not electrically connected to any peripheral device in the peripheral device layer 13. The peripheral interconnection layer 12 further comprises one or more interlayer dielectric (ILD) layers (also referred to as “intermetallic dielectric (IMD) layers”) 129, in which interconnection wires and via hole contacts may be formed. That is, the peripheral interconnection layer 12 may comprise the interconnection portions 1210 in the plurality of ILD layers. The interconnection portions 1210 in the peripheral interconnection layer 12 may include a conductive material, including, but not limited to, tungsten (W), cobalt (Co), copper (Cu), silicide, or any combination thereof. The ILD in the peripheral interconnection layer 12 may include a dielectric material, including, but not limited to, silicon oxide, silicon nitride, silicon oxynitride, a low dielectric constant (low-k) dielectric, or any combination thereof.

As shown in FIG. 31, the peripheral device chip 10 may further comprise a bonding layer 11 (which may be the first bonding layer) at the bonding interface and above the peripheral interconnection layer 12 and the peripheral device layer 13. The bonding layer 11 may comprise a plurality of bonding contacts 112 and 113, and the dielectric layer 111 electrically isolating the bonding contacts 112 and 113. The bonding contacts 112 may be functional bonding contacts, and each functional bonding contact 112 is a part of the electrical connection between the peripheral device chip 10 and the memory array device chip 40. The bonding contacts 113 may be dummy bonding contacts, and each dummy bonding contact 113 is not a part of any electrical connection between the peripheral device chip 10 and the memory array device chip 40. As described in detail below, the dummy bonding contact 113 may be used to increase a local density of bonding contacts at the bonding interface, so as to increase the bonding yield and strength. The bonding contacts may include a conductive material, including, but not limited to, W, Co, Cu, Al, silicide, or any combination thereof. The remaining region of the bonding layer 11 may be formed by the dielectric layer 111, the dielectric layer 111 including, but not limited to, silicon oxide, silicon nitride, silicon oxynitride, a low-k dielectric, or any combination thereof. The bonding contacts and the dielectric layer 111 in the bonding layer 11 may be used for hybrid bonding.

In some examples, the memory array device chip 40 is a NAND flash memory device, in which memory cells are provided in the form of an array of NAND memory strings, with each memory string extending vertically above the peripheral device layer 13. The memory array device layer 43 may comprise the NAND memory strings that extend vertically through a plurality of pairs each comprising a conductor layer and a dielectric layer (herein referred to as a “conductor/dielectric layer pair”). The stacked conductor/dielectric layer pairs are also referred to as a “memory stack” herein. The conductor layers and the dielectric layers in the memory may be stacked alternately in the vertical direction.

As shown in FIG. 31, each NAND memory string may comprise a semiconductor channel 4311 and a dielectric layer 431 (also referred to as a “memory film”). In some examples, the semiconductor channel 4311 includes silicon, e.g., amorphous silicon, polysilicon, or monocrystalline silicon. In some examples, the memory film is a composite layer comprising a tunneling layer 4312, a storage layer 4313 (also referred to as a “charge trap/storage layer”), and a barrier layer (not shown). Each NAND memory string may have a cylindrical shape (e.g., a pillar shape). According to some examples, the semiconductor channel 4311, the tunneling layer 4312, the storage layer 4313, and the barrier layer are arranged sequentially along a radial direction from the center toward an outer surface of the pillar. The tunneling layer 4312 may include silicon oxide, silicon oxynitride, or any combination thereof. The storage layer 4313 may include silicon nitride, silicon oxynitride, or any combination thereof. The barrier layer may include silicon oxide, silicon oxynitride, a high-k dielectric, or any combination thereof.

In some examples, each NAND memory string further comprises a plurality of control gates (each control gate is a part of a word line). Each conductor layer in the memory stack may be used as a control gate of a memory cell of each NAND memory string. Each NAND memory string may comprise a source select gate at its upper end and a drain select gate at its lower end. As used herein, an “upper end” of a component (e.g., the NAND memory string) is an end away from the substrate 14 in the Z direction, and a “lower end” of a component (e.g., the NAND memory string) is an end close to the substrate 14 in the Z direction.

In some examples, the memory array device chip 40 further comprises a semiconductor layer 44 disposed above and in contact with the NAND memory string. The memory array device layer 43 may be disposed below the semiconductor layer 44. In some examples, the semiconductor layer 44 comprises a plurality of semiconductor plugs 48 electrically isolated by an isolation region. In some examples, each semiconductor plug 48 is disposed at the upper end of a respective NAND memory string and used as a drain of the respective NAND memory string, and therefore may be considered as a part of the respective NAND memory string. The semiconductor plug 48 may include monocrystalline silicon. The semiconductor plug 48 may be undoped, partially doped with a p-type or n-type dopant (in at least one of a thickness direction or a width direction), or fully doped.

In some examples, the memory array device chip 40 comprises local interconnections that are formed in one or more IDL layers and in contact with components such as the word line (e.g., the conductor layer) and the NAND memory string in the memory array device layer 43. The local interconnections may comprise a word line via-hole contact 47, a source line via-hole contact 46, and a bit line via-hole contact 49. Each local interconnection may include a conductive material, including, but not limited to, W/Co, Cu, Al, silicide, or any combination thereof. The word line via-hole contact 47 may extend vertically through one or more ILD layers. Each word line via-hole contact may be in contact with a respective conductor layer, so as to address a respective word line of the bonded semiconductor device individually. Each source line via-hole contact 46 may be in contact with the source of the respective NAND memory string. The bit line via-hole contact 49 may extend vertically through one or more ILD layers. Each bit line via-hole contact 49 may be electrically connected to the respective semiconductor plug 48 (e.g., the drain) of the NAND memory string, so as to address the respective NAND memory string individually.

Similar to the peripheral device chip 10, the memory array device chip 40 may further comprise an interconnection layer for performing electrical signal transmission to and from the NAND memory string. As shown in FIG. 31, the memory array device chip 40 may comprise an interconnection layer 42 (herein referred to as an “array interconnection layer” or the “second interconnection layer”) below the memory array device layer 43. The array interconnection layer 42 may comprise a plurality of interconnection portions 4210, including interconnection wires and via hole contacts in one or more ILD layers 429. As described in detail below, the interconnection portions 4210 in the array interconnection layer 42 may comprise a functional interconnection electrically connected to the NAND memory string, and in an example, further comprise a dummy interconnection that is not electrically connected to any NAND memory string in the memory array device layer 43.

As shown in FIG. 31, the memory array device chip 40 may further comprise a bonding layer 41 at the bonding interface and below the array interconnection layer 42 and the memory array device layer 43. The bonding layer 41 may comprise a plurality of bonding contacts 412 and 413, and the second dielectric layer 411 electrically isolating the bonding contacts 412 and 413. The bonding contacts 412 may be functional bonding contacts, and each functional bonding contact is a part of the electrical connection between the peripheral device chip 10 and the memory array device chip 40. The bonding contacts 413 may be dummy bonding contacts, and each dummy bonding contact is not a part of any electrical connection between the peripheral device chip 10 and the memory array device chip 40. The dummy bonding contacts may be used to increase a local density of bonding contacts at the bonding interface, so as to increase the bonding yield and strength.

The bonding contacts 412 and 413 may include a conductive material, including, but not limited to, W, Co, Cu, Al, silicide, or any combination thereof. The remaining region of the bonding layer 41 may be formed by the second dielectric layer 411, the second dielectric layer 411 including, but not limited to, silicon oxide, silicon nitride, silicon oxynitride, a low-k dielectric, or any combination thereof. The bonding contacts and the second dielectric layer 411 in the bonding layer 41 may be used for hybrid bonding as described in detail below.

As shown in FIG. 31, another interconnection layer (herein referred to as a “BEOL interconnection layer”) may be disposed above the memory array device layer 43, and may comprise interconnections such as an interconnection wire 451 and a via hole contact 452 in one or more ILD layers. The BEOL interconnection layer 45 may further comprise a contact pad 453 and a redistribution layer (not shown) at the top of the semiconductor device that are used for at least one of wire bonding or interposer bonding. The BEOL interconnection layer 45 and the array interconnection layer 42 may be formed on opposite sides of the memory array device layer 43. In some examples, the interconnection wire 451, the via hole contact 452, and contact pad 453 in the BEOL interconnection layer 45 may transmit electrical signal between the bonded semiconductor device and an external circuit.

As shown in FIG. 31, the bonding interface may be formed between the bonding layers 11 and 41. According to some examples, the bonding contact 112 contacts the bonding contact 412 at the bonding interface, and the dielectric layer 111 contacts the second dielectric layer 411. A pair of dummy bonding contacts 113 and 413 also contact each other at the bonding interface. As dummy bonding contacts for improving the metal density and uniformity at the bonding interface for the hybrid bonding, the pairwise dummy bonding contacts 113 and 413 are spaced apart from the functional interconnection on at least one side of the bonding interface (e.g., in at least one of the peripheral interconnection layer 12 or the array interconnection layer 42), so as to avoid the formation of an electrical connection between the memory array device chip 40 and the peripheral device chip 10. In some examples, the peripheral interconnection layer 12 and the array interconnection layer 42 comprise a pair of dummy interconnections that are not electrically connected to the NAND memory string and the transistor 131, and a pair of dummy bonding contacts 113 and 413 may respectively contact the pair of dummy interconnections on opposite sides of the bonding interface, without forming an electrical connection between the memory array device chip 40 and the peripheral device chip 10.

The other contents of the example of FIG. 31 may be referred to the above examples.

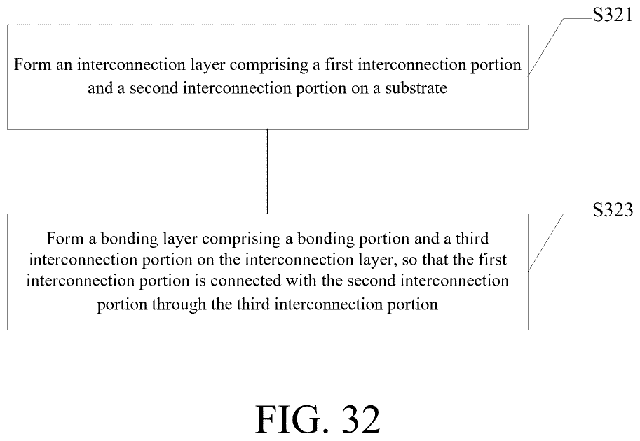

FIG. 32 illustrates a flow chart of a fabrication method of a semiconductor structure in an example of the present disclosure. As shown in FIG. 32, the method provided by the example of the present disclosure may comprise the following operations.

In S321, an interconnection layer comprising a first interconnection portion and a second interconnection portion is formed on a substrate.

The interconnection layer comprising a plurality of interconnection portions (including the first interconnection portion and the second interconnection portion mentioned above) is formed above the substrate. The substrate may be a silicon substrate. In some examples, prior to forming the interconnection layer, a device layer is formed between the substrate and the interconnection layer. The device layer may comprise a NAND memory string or a peripheral device.

In some examples, the device layer is a peripheral device layer comprising a plurality of transistors formed on the silicon substrate through a plurality of processes (including, but not limited to, lithography, dry/wet etching, thin film deposition, thermal growth, implantation, CMP, and any other suitable processes).

In some examples, the device layer is a memory array device layer comprising a plurality of NAND memory strings, with each NAND memory string extending vertically through a memory stack formed on the silicon substrate. In order to form the memory stack, a dielectric stack comprising an alternating stack of sacrificial layers (e.g., silicon nitride) and dielectric layers (e.g., silicon oxide) may be formed on the silicon substrate through one or more thin film deposition processes (including, but not limited to, CVD, physical vapor deposition (PVD), atomic layer deposition (ALD), or any combination thereof). Then, the memory stack may be formed on the silicon substrate through a gate replacement process (i.e., replacing the sacrificial layers in the dielectric stack with conductor layers). In some examples, a manufacturing process for forming the NAND memory string comprises forming a semiconductor channel extending vertically through the dielectric stack, and forming a composite dielectric layer (memory film) between the semiconductor channel and the dielectric stack, which includes, but is not limited to, a tunneling layer, a storage layer, and a barrier layer. The semiconductor channel and memory film may be formed through one or more thin film deposition processes (e.g., ALD, CVD, PVD, any other suitable processes, or any combination thereof).

The interconnection layer is formed above the device layer. The interconnection layer may comprise interconnection portions, including interconnection wires and via hole contacts in one or more ILD layers, so as to implement an electrical connection with a device. In some examples, the interconnection layer comprises a plurality of ILD layers and interconnection portions formed therein through a plurality of processes. For example, the interconnection portions may include a conductive material deposited through one or more thin film deposition processes (including, but not limited to, CVD, PVD, ALD, electrochemical deposition, or any combination thereof). The ILD layers may include a dielectric material deposited through one or more thin film deposition processes (including, but not limited to, CVD, PVD, ALD, or any combination thereof).

In S323, a bonding layer comprising a bonding portion and a third interconnection portion is formed on the interconnection layer, so that the first interconnection portion is connected with the second interconnection portion through the third interconnection portion.

The bonding layer comprising a plurality of first bonding contacts and second bonding contacts is formed above the interconnection layer, so that a part of interconnection portions contact a respective one of the first bonding contacts and a part of interconnection portions do not contact the second bonding contacts. A dielectric layer may also be formed in the bonding layer. In some examples, the first bonding contacts in the bonding layer are formed through a single patterning process.

A layer of dielectric layer is deposited on a top surface of the interconnection layer through a thin film deposition process (including, but not limited to, CVD, PVD, ALD, or any combination thereof). According to some examples, the first bonding contacts and the second bonding contacts are formed in the dielectric layer, so as to form the bonding layer above the interconnection layer and the device layer. The first bonding contacts may be patterned through a single patterning process that involves only one lithographic process. The excessive conductor may be removed through CMP, and a top surface of the bonding layer may be planarized for bonding.

In an example, the method provided by the example of the present disclosure further comprises: forming the device layer between the substrate and the interconnection layer. The first interconnection portion and the second interconnection portion in the interconnection layer are connected with a device in the device layer.

In an example, the method provided by the example of the present disclosure further comprises: forming the device layer between the substrate and the interconnection layer. The bonding portion comprises the first bonding contact and the second bonding contact, and first bonding contact is connected with the device in the device layer.

In an example, the method provided by the example of the present disclosure further comprises: forming the device layer between the substrate and the interconnection layer. The bonding portion comprises the first bonding contact and the first bonding wire, and the first bonding contact is connected with the device in the device layer.

Other contents of the fabrication method of a semiconductor structure provided by an implementation of the present disclosure may be referred to the above examples.

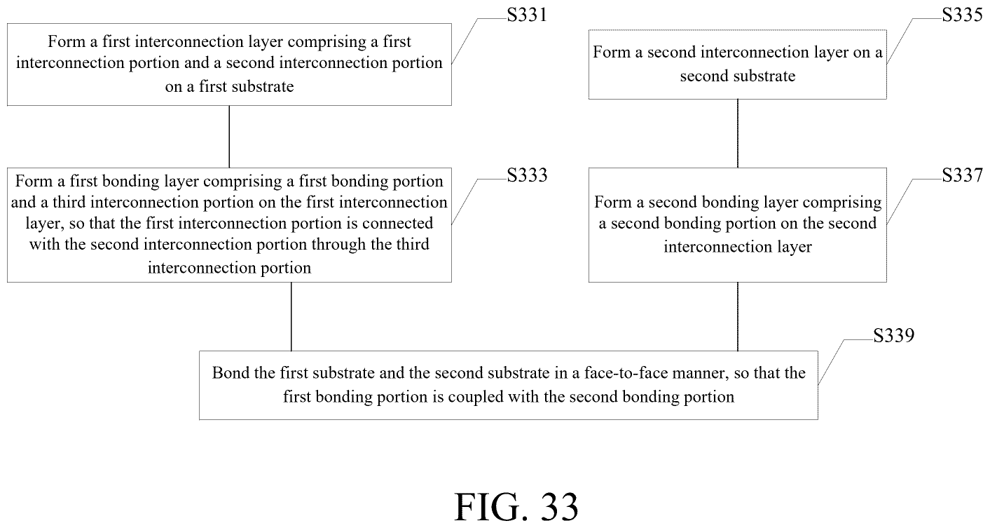

FIG. 33 illustrates a flow chart of a fabrication method of a semiconductor device in an example of the present disclosure. As shown in FIG. 33, the method provided by the example of the present disclosure may comprise the following operations.

In S331, a first interconnection layer comprising a first interconnection portion and a second interconnection portion is formed on a first substrate.

In S333, a first bonding layer comprising a first bonding portion and a third interconnection portion is formed on the first interconnection layer, so that the first interconnection portion is connected with the second interconnection portion through the third interconnection portion.

In S335, a second interconnection layer is formed on a second substrate.

The second interconnection layer comprising a plurality of interconnection portions is formed on the second substrate. The second substrate may be a silicon substrate. In some examples, prior to forming the second interconnection layer, a second device layer is formed between the second substrate and the second interconnection layer. The second device layer may comprise a peripheral device or NAND memory string.

In S337, a second bonding layer comprising a second bonding portion is formed on the second interconnection layer.

The second bonding layer comprising a plurality of third bonding contacts and fourth bonding contacts is formed on the second interconnection layer.

In S339, the first substrate and the second substrate are bonded in a face-to-face manner, so that the first bonding portion is coupled with the second bonding portion.

The first substrate and the second substrate are bonded in a face-to-face manner, so that each first bonding contact contacts one of the third bonding contacts and the second bonding contact contacts one of the fourth bonding contacts at a bonding interface. The bonding may be hybrid bonding.

In an example, the method provided by the example of the present disclosure further comprises: forming a second device layer between the second substrate and the second interconnection layer. The second bonding portion comprises a third bonding contact and a fourth bonding contact, the third bonding contact is connected with a second device in the second device layer, and the third interconnection portion is coupled with the fourth bonding contact.

In an example, the method provided by the example of the present disclosure further comprises: forming a second device layer between the second substrate and the second interconnection layer. The second bonding portion comprises a third bonding contact and a second bonding wire, the third bonding contact is connected with a second device in the second device layer, and the third interconnection portion is coupled with the second bonding wire.

In an example, the method provided by the example of the present disclosure further comprises: forming a first device layer between the first substrate and the first interconnection layer. The second interconnection layer comprises a fourth interconnection portion and a fifth interconnection portion, the second bonding layer further comprises a sixth interconnection portion, and the fourth interconnection portion is connected with the fifth interconnection portion through the sixth interconnection portion. The first bonding portion comprises a first bonding contact and a second bonding contact, the first bonding contact is connected with a first device in the first device layer, and the sixth interconnection portion is coupled with the second bonding contact.

In an example, the method provided by the example of the present disclosure further comprises: forming a first device layer between the first substrate and the first interconnection layer. The second interconnection layer comprises a fourth interconnection portion and a fifth interconnection portion, the second bonding layer further comprises a sixth interconnection portion, and the fourth interconnection portion is connected with the fifth interconnection portion through the sixth interconnection portion. The first bonding portion comprises a first bonding contact and a first bonding wire, the first bonding contact is connected with a first device in the first device layer, and the sixth interconnection portion is coupled with the first bonding wire.

Other contents of the fabrication method of a semiconductor device provided by an implementation of the present disclosure may be referred to the above other examples.

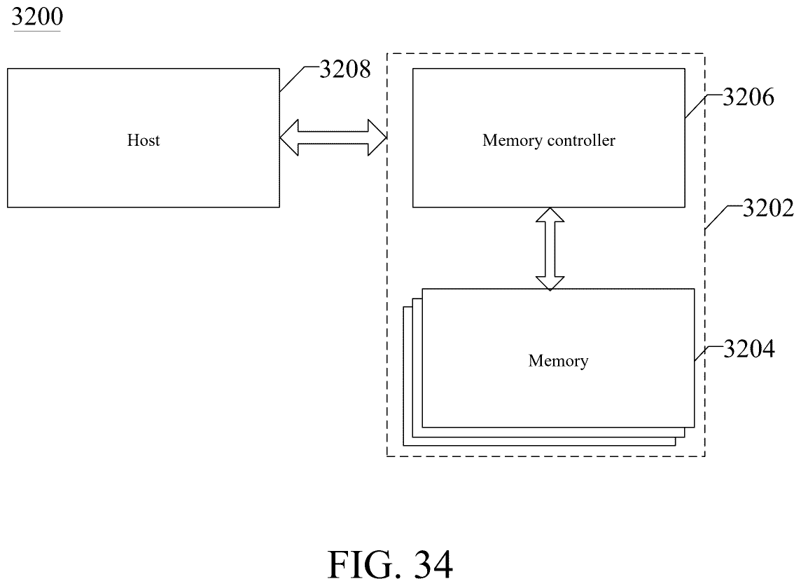

FIG. 34 illustrates a block diagram of an example system having a memory in an example of the present disclosure. The system 3200 may comprise a mobile phone, a desktop computer, a laptop computer, a tablet, a vehicle computer, a gaming console, a printer, a positioning device, a wearable electronic device, a smart sensor, a virtual reality device, an augmented reality device, or any other suitable electronic device having memory therein.

As shown in FIG. 34, the system 3200 may comprise a host 3208 and a memory system 3202, wherein the memory system 3202 has one or more memories 3204 and a memory controller 3206. The host 3208 may be a processor (e.g., a central processing unit (CPU)) of an electronic device or a system on chip (SoC) (e.g., an application processor (AP)). The host 3208 may be configured to send or receive data to or from the memory 3204.

The memory 3204 may be any memory in the present disclosure, for example, a non-volatile memory. The non-volatile memory may be a NAND flash memory (e.g. a three-dimensional (3D) NAND flash memory).

In some examples, the memory controller 3206 is coupled to the memory 3204 and the host 3208, and is configured to control the memory 3204. The memory controller 3206 can manage data stored in the memory 3204 and communicate with the host 3208.

In some examples, the memory controller 3206 is configured to send commands to the memory 3204 to cause the memory 3204 to perform a supply voltage adjustment method provided by an example of the present disclosure.

In some examples, the memory controller 3206 is designed for operating in a low duty-cycle environment like a secure digital (SD) card, a compact flash (CF) card, a universal serial bus (USB) flash drive, or other media for use in electronic device, such as a personal computer, a digital camera, and a mobile phone.

In some examples, the memory controller 3206 is designed for operating in a high duty-cycle environment like a solid state drive (SSD) or an embedded multi-media card (eMMC) which may be used as data storage for mobile device, such as a smartphone, a tablet, and a laptop computer, and enterprise storage array. The memory controller 3206 may be configured to send commands to the memory 3204 to cause the memory 3204 perform operations, such as read, erase, and program operations.

The memory controller 3206 may further be configured to manage various functions with respect to data stored or to be stored in the memory 3204, including, but not limited to, bad-block management, garbage collection, logical-to-physical address conversion, wear leveling, etc.

In some examples, the memory controller 3206 is further configured to process error correction code (ECC) with respect to data read from or written to the memory 3204. The memory controller 3206 may also perform any other suitable functions, e.g., formatting the memory 3204. The memory controller 3206 may communicate with an external device (e.g., the host 3208) according to a particular communication protocol. For example, the memory controller 3206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a firewire protocol, and so on.

The memory controller 3206 and the one or more memories 3204 may be integrated into various types of storage devices, e.g., be included in the same package, such as a universal flash storage (UFS) package or an eMMC package. That is, the memory system 3202 may be implemented and packaged into different types of end electronic products.

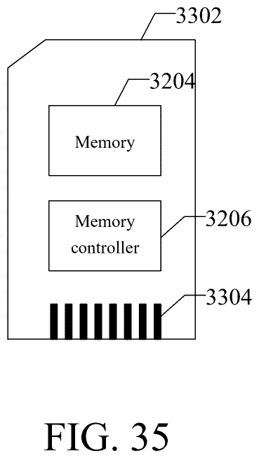

FIG. 35 exemplarily illustrates a block diagram of a memory system. As shown in FIG. 35, the memory controller 3206 and a single memory 3204 may be integrated into a memory card 3302. The memory card 3302 may include a PC card (also referred to as personal computer memory card international association (PCMCIA) card), a CF card, a smart media (SM) card, a memory stick, a multimedia card (e.g., an MMC card, an RS-MMC card, or an MMCmicro card), an SD card (e.g., an SD card, a miniSD card, a microSD card, and or SDHC card), and a UFS card, etc. The memory card 3302 may further comprise a memory card connector 3304 coupling the memory card 3302 with a host (e.g., the host 3208 in FIG. 34).

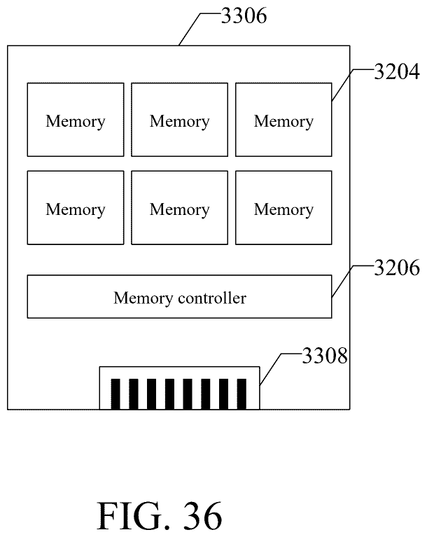

FIG. 36 exemplarily illustrates a block diagram of another memory system. As shown in FIG. 36, the memory controller 3206 and a plurality of memories 3204 may be integrated into an SSD 3306. The SSD 3306 may further comprise an SSD connector 3308 coupling the SSD 3306 with a host (e.g., the host 3208 in FIG. 34). In some examples, at least one of a storage capacity or an operation speed of the SSD 3306 is greater than that of the memory card 3302.

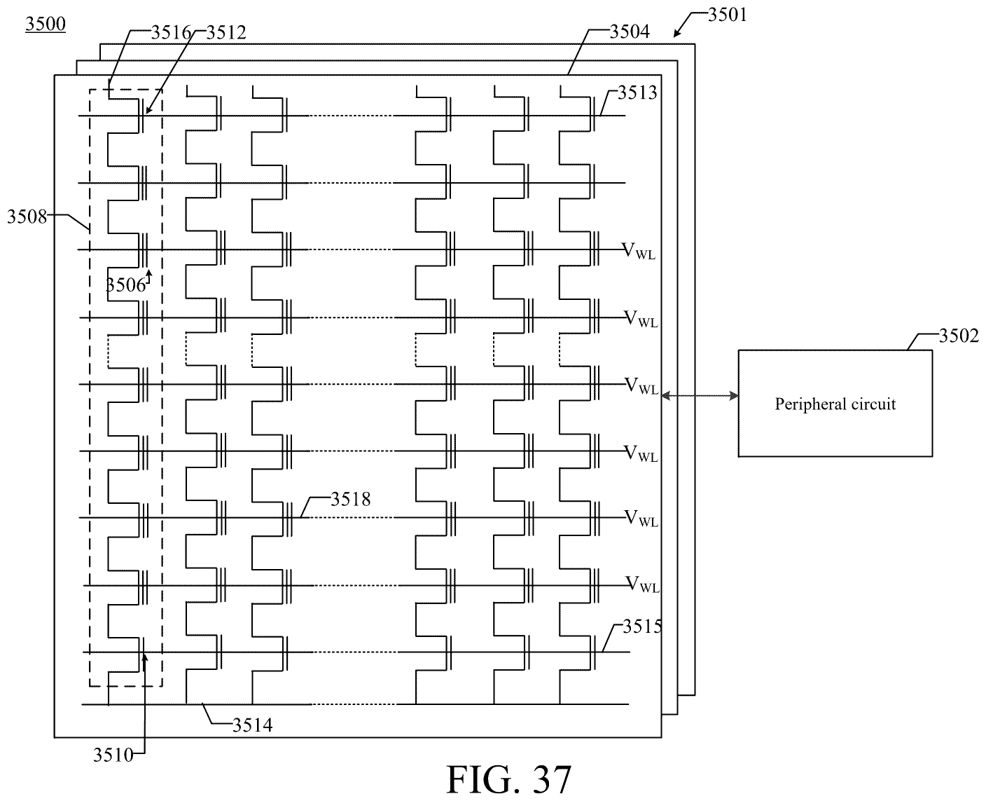

FIG. 37 is a schematic circuit diagram of a memory 3500 comprising a peripheral circuit provided by an example of the present disclosure. The memory 3500 may be an example of the memory 3204 in FIG. 34. The memory device 3500 may comprise a memory cell array 3501 and a peripheral circuit 3502 coupled to the memory cell array 3501. The memory cell array 3501 may be a NAND flash memory cell array, wherein memory cells 3506 are provided in a form of an array of NAND flash memory strings 3508, and each memory string 3508 extends vertically above a substrate (not shown).

In some examples, the peripheral circuit 3502 is configured to perform an operation method provided by an example of the present disclosure. It can be understood that, the peripheral circuit 3502 may be configured to perform the operation method provided by the example of the present disclosure according to instructions received from the memory controller 3206.

In some examples, each memory string 3508 comprises a plurality of memory cells 3506 coupled in series and stacked vertically. Each memory cell 3506 may keep a continuous analog value, such as voltage or charge, which depends on the number of electrons trapped within a region of the memory cell 3506. Each memory cell 3506 may be a floating gate type of memory cell including a floating gate transistor, or a charge trap type of memory cell including a charge trap transistor.

As shown in FIG. 37, each memory string 3508 may comprise a source select gate (SSG) 3510 at a source end thereof and a drain select gate (DSG) 3512 at a drain end thereof. The SSG 3510 and the DSG 3512 may be configured to activate a selected memory string 3508 during read and program operations.

In some examples, sources of the memory strings 3508 in the same block 3504 are coupled through the same source line (SL) 3514 (e.g., a common SL). For example, all the memory strings 3508 in the same block 3504 have an array common source (ACS). As shown in FIG. 37, the memory strings 3508 may be organized into a plurality of blocks 3504, wherein each of the plurality of blocks 3504 may have a common source line 3514 (e.g., coupled to the ground). In some examples, each block 3504 is a basic data unit for an erase operation, i.e., all of the memory cells 3506 on the same block 3504 are erased at the same time.

In some examples, a transistor of the DSG 3512 of each memory string 3508 is coupled to a respective bit line (BL) 3516, and data may be read from or written to the bit line 3516 via an output bus (not shown). Each memory string 3508 may be configured to be selected or unselected by applying a select voltage (e.g., above a threshold voltage of a transistor having the DSG 3512) or an unselect voltage (e.g., 0 V) to a respective TSG 3512 via one or more DSG lines 3513 and/or by applying a select voltage (e.g., above a threshold voltage of a transistor having the SSG 3510) or an unselect voltage (e.g., 0 V) to a respective SSG 3510 via one or more SSG lines 3515.

As shown in FIG. 37, the memory cells 3506 of the memory string 3508 may be coupled through a word line (WL) 3518 that selects which row of memory cells 3506 is affected by the read and program operations. The peripheral circuit 3502 may be coupled to the memory cell array 3501 through the bit line 3516, the word line 3518, the source line 3514, the SSG line 3515, and the DSG line 3513. The peripheral circuit 3502 may include any suitable analog, digital, and mixed signal circuits for facilitating operations of the memory cell array 3501 by applying and sensing at least one of voltage signal or current signal to and from each memory cell 3506 serving as an operation target via the bit line 3516, the word line 3518, the source line 3514, the SSG line 3515, and the DSG line 3513. The peripheral circuit 3502 may include various types of peripheral circuits formed using a metal-oxide-semiconductor (MOS) technology.

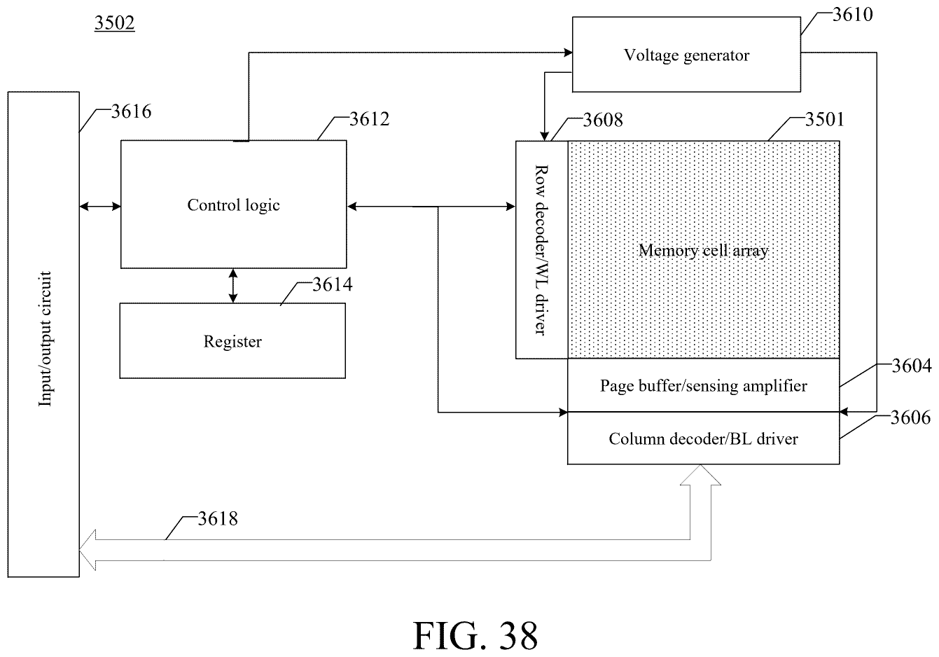

FIG. 38 is a schematic diagram of a peripheral circuit provided by an example of the present disclosure. As shown in FIG. 38, the peripheral circuit 3502 may comprise a functional circuit, a detection circuit, and a regulation circuit. The functional circuit comprises one or more of a page buffer/sensing amplifier 3604, a column decoder/BL driver 3606, a row decoder/WL driver 3608, a voltage generator 3610, a control logic 3612, a register 3614, an input/output (I/O) circuit 3616, and a data bus 3618, etc. It is to be understood that in some examples, additional peripheral circuits not shown in FIG. 38 may be included as well.

In some examples, the page buffer/sensing amplifier 3604 may be configured to read and program (write) data from and to the memory cell array 3501 according to a control signal from the control logic 3612. For example, the page buffer/sensing amplifier 3604 may store one page of program data (write data) to be programmed into the memory cell array 3501. For another example, the page buffer/sensing amplifier 3604 may also sense a low power signal from the bit line 3616 that represents a data bit stored in the memory cell 3606, and amplifies a small voltage swing to a recognizable logic level in a read operation. The column decoder/BL driver 3606 may be configured to be controlled by the control logic 3612, and select one or more memory strings 3508 by applying a bit line voltage generated from the voltage generator 3610.

The row decoder/WL driver 3608 may be configured to be controlled by the control logic 3612, select/unselect the block 3604 of the memory cell array 3501, and select/unselect the word line 3618 of the block 3604. The row decoder/WL driver 3608 may be further configured to drive the word line 3618 using a word line voltage generated from the voltage generator 3610. In some examples, the row decoder/WL driver 3608 may also select/unselect and drive the SSG line 3514 and the DSG line 3513. The voltage generator 3610 may be configured to be controlled by the control logic 3612 and generate a word line voltage (e.g., a read voltage, a program voltage, a pass voltage, a local voltage, or a verify voltage), a bit line voltage, and a source line voltage to be supplied to the memory cell array 3501.

The control logic 3612 may be coupled to each portion of the peripheral circuit 3502 and configured to control operations of each portion. The register 3614 may be coupled to the control logic 3612, and may comprise a status register, a command register, and an address register to store status information, a command operation code (OP code), and a command address for controlling the operations of each peripheral circuit. The input/output circuit 3616 may be coupled to the control logic 3612, and act as a control buffer to buffer and relay a control command received from a host (not shown in FIG. 38) to the control logic 3612, and to buffer and relay the status information received from the control logic 3612 to the host. The input/output circuit 3616 may also be coupled to the column decoder/bit line driver 3606 via the data bus 3618 and act as a data I/O interface and a data buffer to buffer and relay data to and from the memory cell array 3501.

The purpose of the present disclosure is to provide a semiconductor structure, a semiconductor device, a fabrication method of a semiconductor structure, and a fabrication method of a semiconductor device, which can reduce the manufacturing cost.

An example of the present disclosure provide a semiconductor structure comprising: an interconnection layer comprising a first interconnection portion and a second interconnection portion; and a bonding layer comprising a bonding portion and a third interconnection portion. The first interconnection portion is connected with the second interconnection portion through the third interconnection portion.

An example of the present disclosure provide a semiconductor device comprising: a first semiconductor structure and a second semiconductor structure. The first semiconductor structure comprises: a first interconnection layer comprising a first interconnection portion and a second interconnection portion; and a first bonding layer comprising a first bonding portion and a third interconnection portion, wherein the first interconnection portion is connected with the second interconnection portion through the third interconnection portion. The second semiconductor structure comprises: a second interconnection layer; and a second bonding layer comprising a second bonding portion. The first bonding portion is coupled with the second bonding portion.

An example of the present disclosure provide a fabrication method of a semiconductor structure, comprising: forming an interconnection layer comprising a first interconnection portion and a second interconnection portion on a substrate; and forming a bonding layer comprising a bonding portion and a third interconnection portion on the interconnection layer, so that the first interconnection portion is connected with the second interconnection portion through the third interconnection portion.

An example of the present disclosure provide a fabrication method of a semiconductor device, comprising: forming a first interconnection layer comprising a first interconnection portion and a second interconnection portion on a first substrate; forming a first bonding layer comprising a first bonding portion and a third interconnection portion on the first interconnection layer, so that the first interconnection portion is connected with the second interconnection portion through the third interconnection portion; forming a second interconnection layer on a second substrate; forming a second bonding layer comprising a second bonding portion on the second interconnection layer; and bonding the first substrate and the second substrate in a face-to-face manner, so that the first bonding portion is coupled with the second bonding portion.

In the semiconductor structure provided by some examples of the present disclosure, the number of routing layers of interconnection portions in the interconnection layer can be reduced by disposing the third interconnection portion in the bonding layer, thereby reducing the manufacturing cost.

The examples of the present disclosure are shown and described in detail above. It is to be understood that, the present disclosure is not limited to the particular structures, configuration manners, or implementation methods described herein; rather, the present disclosure is intended to cover a variety of modifications and equivalent configurations encompassed within the spirit and scope of the following claims.

What is claimed is:

1. A semiconductor structure, comprising:
an interconnection layer comprising a first interconnection portion and a second interconnection portion; and
a bonding layer comprising a bonding portion and a third interconnection portion,
wherein the first interconnection portion is connected with the second interconnection portion through the third interconnection portion.

2. The semiconductor structure of claim 1, wherein the bonding portion comprises a first bonding contact and a second bonding contact, the semiconductor structure further comprises a device layer, and the first bonding contact is connected with a device in the device layer.

3. The semiconductor structure of claim 1, wherein the bonding portion comprises a first bonding contact and a first bonding wire, the semiconductor structure further comprises a device layer, and the first bonding contact is connected with a device in the device layer.

4. The semiconductor structure of claim 1, further comprising a device layer, wherein the first interconnection portion and the second interconnection portion are connected with a device in the device layer.

5. The semiconductor structure of claim 4, wherein the device included in the device layer is a memory device or a peripheral device.

6. A semiconductor device, comprising:
a first semiconductor structure comprising:
a first interconnection layer comprising a first interconnection portion and a second interconnection portion; and
a first bonding layer comprising a first bonding portion and a third interconnection portion, wherein the first interconnection portion is connected with the second interconnection portion through the third interconnection portion; and
a second semiconductor structure comprising:
a second interconnection layer; and
a second bonding layer comprising a second bonding portion,
wherein the first bonding portion is coupled with the second bonding portion.

7. The semiconductor device of claim 6, wherein the second bonding portion comprises a third bonding contact and a fourth bonding contact, the second semiconductor structure further comprises a second device layer, and the third bonding contact is connected with a second device in the second device layer.

8. The semiconductor device of claim 7, wherein the third interconnection portion is coupled with the fourth bonding contact.

9. The semiconductor device of claim 6, wherein the second bonding portion comprises a third bonding contact and a second bonding wire, the second semiconductor structure further comprises a second device layer, and the third bonding contact is connected with a second device in the second device layer.

10. The semiconductor device of claim 9, wherein the third interconnection portion is coupled with the second bonding wire.

11. The semiconductor device of claim 6, wherein the second interconnection layer comprises a fourth interconnection portion and a fifth interconnection portion, the second bonding layer further comprises a sixth interconnection portion, and the fourth interconnection portion is connected with the fifth interconnection portion through the sixth interconnection portion.

12. The semiconductor device of claim 11, wherein the first bonding portion comprises a first bonding contact and a second bonding contact, the first semiconductor structure further comprises a first device layer, and the first bonding contact is connected with a first device in the first device layer.

13. The semiconductor device of claim 12, wherein the sixth interconnection portion is coupled with the second bonding contact.

14. The semiconductor device of claim 11, wherein the first bonding portion comprises a first bonding contact and a first bonding wire, the first semiconductor structure further comprises a first device layer, and the first bonding contact is connected with a first device in the first device layer.

15. The semiconductor device of claim 6, wherein the first semiconductor structure further comprises a first device layer, wherein the first interconnection portion and the second interconnection portion in the first interconnection layer are connected with a first device in the first device layer; and
the second semiconductor structure further comprises a second device layer, wherein a fourth interconnection portion and a fifth interconnection portion in the second interconnection layer are connected with a second device in the second device layer.

16. The semiconductor device of claim 15, wherein the first device is a memory device or a peripheral device, and the second device is a peripheral device or a memory device.

17. A fabrication method of a semiconductor structure, comprising:
forming an interconnection layer comprising a first interconnection portion and a second interconnection portion on a substrate; and
forming a bonding layer comprising a bonding portion and a third interconnection portion on the interconnection layer, so that the first interconnection portion is connected with the second interconnection portion through the third interconnection portion.

18. The method of claim 17, further comprising forming a device layer between the substrate and the interconnection layer, wherein the first interconnection portion and the second interconnection portion in the interconnection layer are connected with a device in the device layer.

19. The method of claim 17, further comprising forming a device layer between the substrate and the interconnection layer, wherein the bonding portion comprises a first bonding contact and a second bonding contact, and the first bonding contact is connected with a device in the device layer.

20. The method of claim 17, further comprising forming a device layer between the substrate and the interconnection layer, wherein the bonding portion comprises a first bonding contact and a first bonding wire, and first bonding contact is connected with a device in the device layer.
